(19) United States
(12) Patent Application Publication
(10) Pub. No.: US 2026/0173703 A1
(43) Pub. Date: Jun. 18, 2026

(54) DISPLAY PANEL, METHOD FOR PREPARING DISPLAY PANEL, AND ELECTRONIC DEVICE

(71) Applicant: Hefei Visionox Technology Co., Ltd., Hefei (CN)

(72) Inventors: Zengqiang XIA, Hefei (CN); Xuejing ZHU, Hefei (CN); Yiming XIAO, Hefei (CN); Peng QIN, Hefei (CN)

(73) Assignee: Hefei Visionox Technology Co., Ltd., Hefei (CN)

(21) Appl. No.: 19/402,887

(22) Filed: Nov. 26, 2025

(30) Foreign Application Priority Data
Dec. 12, 2024 (CN) 202411841771.3

(51) Int. Cl. H10K 59/38; H10K 59/12; H10K 59/122; H10K 59/80; H10K 102/00

(52) U.S. Cl. CPC H10K 59/38; H10K 59/1201; H10K 59/122; H10K 59/873; H10K 59/8792; H10K 2102/351

(57) ABSTRACT

Embodiments of the present application provide a display panel, a method for preparing a display panel, and an electronic device, which relate to the field of display. The display panel includes a substrate, an isolation structure, light-emitting units, encapsulation units, a filter layer, and a light shielding layer. The isolation structure is located on one side of the substrate. The filter layer includes a plurality of filter portions disposed at intervals. An orthographic projection of the filter portion on the substrate covers an orthographic projection of the light-emitting unit on the substrate. The light shielding layer is located on a side of the isolation structure away from the substrate, and includes a plurality of light shielding portions disposed at intervals. An orthographic projection of the light shielding portion on the substrate at least partially overlaps an orthographic projection of the isolation structure on the substrate.

### CROSS-REFERENCE TO RELATED APPLICATIONS

The present application claims priority to Chinese Patent Application No. 202411841771.3 filed on Dec. 12, 2024, the disclosure of which is incorporated herein by reference in its entirety.

### FIELD

The present application relates to the field of display, and in particular to a display panel, a method for preparing a display panel, and an electronic device.

### BACKGROUND

With the development of display technology, Organic Light Emitting Diode (OLED) display panels are widely used due to advantages of thinness, high brightness, low power consumption, fast response, high clarity, and the like. During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, the display panels still have some issues that need to be urgently addressed.

### SUMMARY

In order to overcome the problems mentioned in the above background art, embodiments of the present application provide a display panel. The display panel includes:
a substrate;
an isolation structure located on one side of the substrate, the isolation structure enclosing isolation openings;
light-emitting units at least partially located in the isolation openings;
encapsulation units located on a side of the light-emitting units away from the substrate, at least part of the encapsulation unit extending from a side surface of the isolation structure facing the isolation opening to a side of the isolation structure away from the substrate;
a filter layer located on the side of the light-emitting unit away from the substrate and including a plurality of filter portions disposed at intervals, an orthographic projection of the filter portion on the substrate at least partially overlapping an orthographic projection of the light-emitting unit on the substrate; and
a light shielding layer located on the side of the isolation structure away from the substrate, the light shielding layer including a plurality of light shielding portions disposed at intervals, where an orthographic projection of the light shielding portion on the substrate at least partially overlaps an orthographic projection of the isolation structure on the substrate; and the orthographic projection of the light shielding portion on the substrate at least partially overlaps the orthographic projection of the filter portion on the substrate.

In some embodiments, the present application further provides a method for preparing a display panel, the method including:
forming an isolation structure on one side of a substrate, the isolation structure enclosing isolation openings;
forming light-emitting units at least partially in the isolation openings, encapsulation units on a side of the light-emitting units away from the substrate, and a filter layer on a side of the encapsulation units away from the substrate, the filter layer including a plurality of filter portions disposed at intervals, an orthographic projection of the filter portion on the substrate at least partially overlapping an orthographic projection of the light-emitting unit on the substrate; and
forming a light shielding layer on a side of the isolation structure away from the substrate, the light shielding layer including a plurality of light shielding portions disposed at intervals, an orthographic projection of the light shielding portion on the substrate at least partially overlapping an orthographic projection of the isolation structure on the substrate, and the orthographic projection of the light shielding portion on the substrate at least partially overlapping the orthographic projection of the filter portion on the substrate.

In some embodiments, the present application further provides an electronic device, including a display panel in the present application, or including a display panel prepared by means of a method for preparing a display panel in the present application.

The present application has the following beneficial effects with respect to the prior art.

The present application provides a display panel, a method for preparing a display panel, and an electronic device, in which the orthographic projection of the light shielding portion on the substrate at least partially overlaps the orthographic projection of the filter portion on the substrate, and the reflectivity of ambient light can be reduced while improving the light extraction efficiency of the light-emitting unit, and the display effect of the display panel can thus be improved.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope.

FIG. 1 is a schematic cross-sectional view of a display panel in the related art according to an embodiment of the present application;

FIG. 2 is a first schematic cross-sectional view of a display panel according to an embodiment of the present application;

FIG. 3 is a first schematic top view showing a light shielding portion, a pixel opening and an isolation opening according to an embodiment of the present application;

FIG. 4a is a second schematic cross-sectional view of a display panel according to an embodiment of the present application;

FIG. 4b is a second schematic top view showing the light shielding portion, the pixel opening and the isolation opening according to an embodiment of the present application;

FIG. 4c is a first schematic cross-sectional view of FIG. 4b taken along line A-A according to an embodiment of the present application;

FIG. 4d is a second schematic cross-sectional view of FIG. 4b taken along line A-A according to an embodiment of the present application;

FIG. 4e is a third schematic top view showing the light shielding portion, the pixel opening and the isolation opening according to an embodiment of the present application;

FIG. 5 is a schematic cross-sectional view of a display panel including a second encapsulation layer and a third encapsulation layer according to an embodiment of the present application;

FIG. 6 is a first schematic flowchart of a method for preparing a display panel according to an embodiment of the present application;

FIG. 7 is a schematic cross-sectional view of a first electrode layer formed on one side of a substrate according to an embodiment of the present application;

FIG. 8 is a schematic cross-sectional view of a pixel defining material layer formed on a side of the first electrode layer away from the substrate according to an embodiment of the present application;

FIG. 9 is a schematic cross-sectional view of an isolation material layer formed on a side of the pixel defining material layer away from the substrate according to an embodiment of the present application;

FIG. 10 is a schematic cross-sectional view of a patterned isolation material layer forming an isolation structure according to an embodiment of the present application;

FIG. 11 is a schematic cross-sectional view of a patterned pixel defining material layer forming a pixel defining layer according to an embodiment of the present application;

FIG. 12 is a schematic cross-sectional view of a first light-emitting unit, an encapsulation unit, and a first filter portion formed in a first isolation opening according to an embodiment of the present application;

FIG. 13 is a schematic cross-sectional view of a second light-emitting unit, an encapsulation unit, and a second filter portion formed in a second isolation opening according to an embodiment of the present application;

FIG. 14 is a schematic cross-sectional view of a third light-emitting unit, an encapsulation unit, and a third filter portion formed in a third isolation opening according to an embodiment of the present application;

FIG. 15 is a schematic cross-sectional view of the first light-emitting unit formed in the first isolation opening and the encapsulation unit formed on a side of the first light-emitting unit away from the substrate according to an embodiment of the present application;

FIG. 16 is a schematic cross-sectional view of the second light-emitting unit formed in the second isolation opening and the encapsulation unit formed on a side of the second light-emitting unit away from the substrate according to an embodiment of the present application;

FIG. 17 is a schematic cross-sectional view of the third light-emitting unit formed in the third isolation opening and the encapsulation unit formed on a side of the third light-emitting unit away from the substrate according to an embodiment of the present application;

FIG. 18 is a schematic cross-sectional view of the second encapsulation layer formed on a side of a filter layer and a light shielding layer away from the substrate according to an embodiment of the present application;

FIG. 19 is a second schematic flowchart of a method for preparing a display panel according to an embodiment of the present application;

FIG. 20 is a schematic cross-sectional view of the first filter portion formed on the side of the first light-emitting unit away from the substrate according to an embodiment of the present application; and

FIG. 21 is a schematic cross-sectional view of the second filter portion formed on the side of the second light-emitting unit away from the substrate according to an embodiment of the present application.

### DETAILED DESCRIPTION OF THE EMBODIMENTS

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

Referring to FIG. 1, a display panel in the related art includes a substrate 1, an isolation structure 3 located on one side of the substrate 1, the isolation structure 3 enclosing isolation openings 8, light-emitting units 7 located in the isolation openings 8, and a first encapsulation layer 9, a second encapsulation layer 10, a third encapsulation layer 11 and a color conversion layer 12 sequentially stacked on a side of each light-emitting unit 7 away from the substrate 1. The color conversion layer 12 includes a filter unit 121 and a shielding unit 122.

However, the color conversion layer 12 in the related art is located on a side of the third encapsulation layer 11 away from the substrate 1, and the color conversion layer 12 is relatively far from the light-emitting unit 7, and the shielding unit 122 is likely to shield light at a wide viewing angle from the light-emitting unit 7, thereby affecting the light extraction efficiency of the light-emitting unit 7. Moreover, a side surface of the filter unit 121 is in contact with a side surface of the shielding unit 122, and the shielding unit 122 has a limited area for absorbing light; therefore, the shielding unit 122 has a limited effect on reducing the reflectivity of ambient light, finally affecting the display effect of the display panel.

In order to solve the above-mentioned problem, the inventors have innovatively designed the following embodiments. The specific implementations of the present application will be described in detail below with reference to the accompanying drawings. It should be noted that the defects of the above solutions in the prior art are the results obtained by the inventors after practice and careful research. Therefore, the process of discovering the above problem and the embodiments for the above problem should be regarded as the contributions made by the inventors to the present application during invention and creation, and should not be construed as the content that is well known in the art.

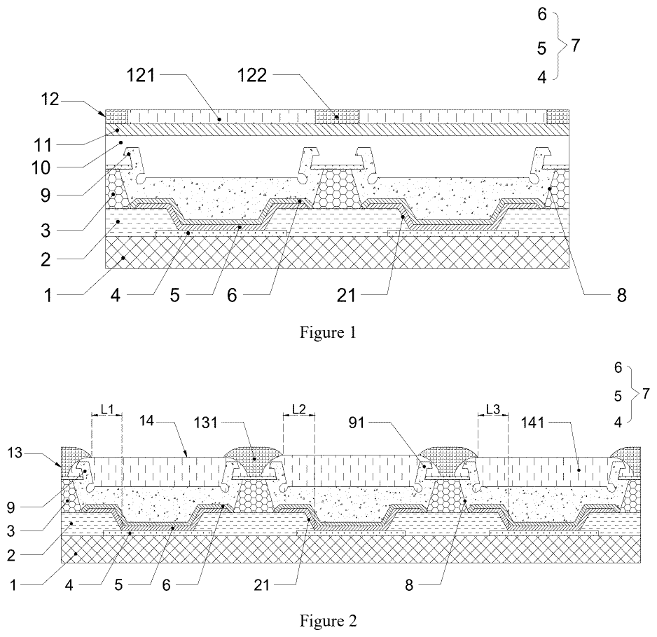

Referring to FIG. 2, this embodiment provides a display panel, including a substrate 1, an isolation structure 3, light-emitting units 7, a filter layer 14, and a light shielding layer 13.

The substrate 1 may include a base substrate and a plurality of drive units located on one side of the base substrate. Each drive unit may include one or more semiconductor switching devices. The semiconductor switching device may be formed collectively by a plurality of film layers in the substrate 1. For example, the semiconductor switching device may be a thin film transistor formed collectively by the plurality of film layers.

The isolation structure 3 is located on one side of the substrate 1, and the isolation structure 3 encloses isolation openings 8. The light-emitting units 7 are at least partially located in the isolation openings 8.

Encapsulation units 91 are located on a side of the light-emitting units 7 away from the substrate 1. A plurality of encapsulation units 91 form a first encapsulation layer 9. At least part of the encapsulation unit 91 extends from a side surface of the isolation structure 3 facing the isolation opening 8 to a side of the isolation structure 3 away from the substrate 1.

The filter layer 14 is located on the side of the light-emitting units 7 away from the substrate 1, and the filter layer 14 includes a plurality of filter portions 141 disposed at intervals. An orthographic projection of the filter portion 141 on the substrate 1 at least partially overlaps an orthographic projection of the light-emitting unit 7 on the substrate 1.

A filter color of the filter portion 141 is the same as a light-emitting color of the corresponding light-emitting unit 7, and the filter portion 141 can allows light emitted by the corresponding light-emitting unit 7 to pass through and filters out light of different colors emitted by the other light-emitting units 7. For example, the light emitted by the light-emitting unit 7 is red, and the filter portion 141 corresponding to the light-emitting unit 7 can allow the red light to pass through and filters out the light other than red light. Therefore, the filter portion 141 can improve the light extraction efficiency of the light-emitting unit 7.

The light shielding layer 13 is located on the side of the isolation structure 3 away from the substrate 1, and the light shielding layer 13 includes a plurality of light shielding portions 131 disposed at intervals. An orthographic projection of the light shielding portion 131 on the substrate 1 at least partially overlaps an orthographic projection of the isolation structure 3 on the substrate 1, and the orthographic projection of the light shielding portion 131 on the substrate 1 at least partially overlaps the orthographic projection of the filter portion 141 on the substrate 1. The filter portions 141 and the light shielding portions 131 are spaced apart in a direction of arrangement of the isolation openings 8.

A material of the light shielding portion 131 may include black rubber, and light emitted by the light-emitting unit 7 generally cannot pass through the light shielding portion 131. In this embodiment, the light shielding portion 131 is disposed on the side of the isolation structure 3 away from the substrate 1, and a distance between the light shielding portion 131 and the light-emitting unit 7 can be reduced. Therefore, the amount of light at a wide viewing angle from the light-emitting unit 7 that is shielded by the light shielding portion 131 can be reduced, and the amount of light extracted from the light-emitting unit 7 at a wide viewing angle can be increased.

The light shielding portion 131 can absorb the light irradiated from the outside, and reduce the reflectivity of ambient light, and the light extraction effect of the light-emitting unit 7 can be improved. In this embodiment, by setting the orthographic projection of the light shielding portion 131 on the substrate 1 to at least partially overlap the orthographic projection of the filter portion 141 on the substrate 1, the absorption area of the light shielding portion 131 for the ambient light can be increased, and the reflectivity of the ambient light can thus be further reduced.

Based on the above design, in this embodiment, by setting the orthographic projection of the light shielding portion 131 on the substrate 1 to at least partially overlap the orthographic projection of the filter portion 141 on the substrate 1, it is possible to reduce the reflectivity of the ambient light while improving the light extraction efficiency of the light-emitting unit 7, and thus to improve the display effect of the display panel.

In some embodiments, referring again to FIG. 2, part of the light shielding portion 131 extends to a side of the filter portion 141 away from the substrate 1.

By extending part of the light shielding portion 131 to the side of the filter portion 141 away from the substrate 1, the absorption area of the light shielding portion 131 for the ambient light can be increased, and the reflectivity of the ambient light can thus be further reduced.

In some embodiments, the display panel further includes a pixel defining layer 2 located on one side of the substrate 1. The isolation structure 3 is located on a side of the pixel defining layer 2 away from the substrate 1. Each light-emitting unit 7 includes a first electrode 4, a light-emitting portion 5 and a second electrode 6 sequentially stacked in a direction away from the substrate 1, and the pixel defining layer 2 includes pixel openings 21 at least partially exposing the first electrodes 4. An orthographic projection of the pixel opening 21 on the substrate 1 is located within an orthographic projection of the isolation opening 8 on the substrate 1.

The provision of the isolation structure 3 enables the display panel to form film layers of the light-emitting units 7 of different colors in different isolation openings 8 without the need for a fine metal mask. Specifically, when a light-emitting functional layer is formed, the light-emitting functional layer may be separated by the isolation structure 3 to form a plurality of light-emitting portions 5 disposed at intervals; and when a second electrode layer is formed, the second electrode layer may be separated by the isolation structure 3 to form a plurality of second electrodes 6 disposed at intervals. The isolation structure 3 includes a conductive material, the second electrode 6 is electrically connected to the isolation structure 3, and one first electrode 4, one light-emitting portion 5 and one second electrode 6 form one light-emitting unit 7. The first electrode 4 may be an anode, and the second electrode 6 may be a cathode.

In this way, different light-emitting units 7 can be made independent of each other, and the crosstalk between adjacent light-emitting units 7 can be alleviated and the display effect of the display panel can be improved. Furthermore, due to the presence of the isolation structure 3, each of the light-emitting functional layer and the second electrode layer of the light-emitting unit 7 of each color in the display panel can be prepared over its entire surface first and then patterned, thereby eliminating the need for a fine metal mask and reducing the preparation cost of the display panel.

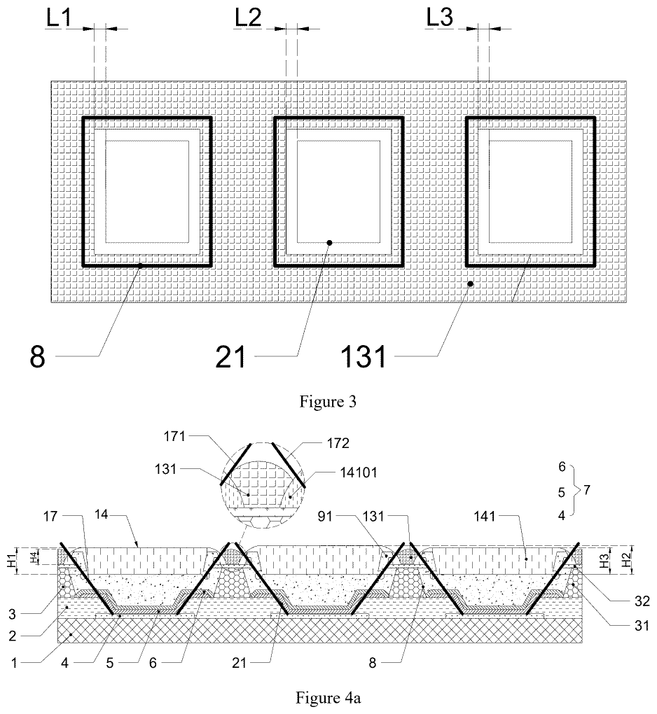

In some embodiments, referring to FIGS. 2 and 3, an orthographic projection on the substrate 1 of a side of the light shielding portion 131 close to the isolation opening 8 is located between an edge of the orthographic projection of the pixel opening 21 on the substrate 1 and an edge of the orthographic projection of the isolation opening 8 on the substrate 1.

The pixel opening 21 in this embodiment refers to an area formed by enclosing a side of the pixel opening 21 close to the substrate 1, the isolation opening 8 refers to an opening formed by enclosing the side of the isolation structure 3 away from the substrate 1, and the light shielding portion 131 extends in the direction of the isolation opening 8 between the pixel opening 21 and the isolation opening 8, and the absorption effect of the light shielding portion 131 on the ambient light can be further improved, to further reduce the reflectivity of the ambient light, the influence of the ambient light on the light emitted by the light-emitting unit 7 can thus be further reduced, and the display effect of the light-emitting unit 7 can thus be further improved.

In some embodiments, the orthographic projection of the filter portion 141 on the substrate 1 at least partially overlaps the orthographic projection of the isolation structure 3 on the substrate 1. The filter portion 141 extends to the side of the isolation structure 3 away from the substrate 1, and the filter portion 141 has a better filter effect on the light-emitting unit 7, and the light extraction efficiency of the light-emitting unit 7 can thus be further improved.

In some embodiments, the filter portion 141 includes a filter sub-portion 14101 located on a side of the isolation structure 3 away from the substrate 1, and the light shielding portion 131 extends to a side of the filter sub-portion 14101 away from the substrate 1. In this way, the absorption area of the light shielding portion 131 for the ambient light can be increased, and the reflectivity of the ambient light can thus be further reduced.

In some embodiments, a minimum distance between an orthographic projection on the substrate 1 of a side of the light shielding portion 131 facing the isolation opening 8 and the edge of the orthographic projection of the pixel opening 21 on the substrate 1 is greater than or equal to 1 μm and less than or equal to 2 μm, for example, which may be 1 μm, 1.1 μm, 1.3 μm, 1.5 μm, 1.7 μm, 1.9 μm, or 2 μm. The proper setting of the distance by which the light shielding portion 131 extends in the direction of the isolation opening 8 can further reduce the reflectivity of the ambient light without affecting the light extraction of the light-emitting unit 7.

In some embodiments, the light-emitting units 7 include a first light-emitting unit, a second light-emitting unit and a third light-emitting unit of different light-emitting colors. A minimum distance L2 between an orthographic projection on the substrate 1 of a side facing the isolation opening 8 of the light shielding portion 131 corresponding to the second light-emitting unit and the edge of the orthographic projection of the pixel opening 21 on the substrate 1 is greater than a minimum distance L1 between an orthographic projection on the substrate 1 of a side facing the isolation opening 8 of the light shielding portion 131 corresponding to the first light-emitting unit and the edge of the orthographic projection of the pixel opening 21 on the substrate 1, and a minimum distance L3 between an orthographic projection on the substrate 1 of a side facing the isolation opening 8 of the light shielding portion 131 corresponding to the third light-emitting unit and the edge of the orthographic projection of the pixel opening 21 on the substrate 1

The first light-emitting unit has a greater light-emitting wavelength than the second light-emitting unit, and the second light-emitting unit has a greater light-emitting wavelength than the third light-emitting unit. For example, a light-emitting color of the first light-emitting unit is red, a light-emitting color of the second light-emitting unit is green, and a light-emitting color of the third light-emitting unit is blue. The human eye is more sensitive to green than red and blue. In this embodiment, by setting the minimum distance L2 to be greater than the minimum distance L1 and the minimum distance L3, it is possible to reduce the amount of light that is emitted by the second light-emitting unit and shielded by the light shielding portion, and thus to further improve the overall display effect of the display panel.

Specifically, the minimum distance L1 between the orthographic projection on the substrate 1 of the side facing the isolation opening 8 of the light shielding portion 131 corresponding to the first light-emitting unit and the edge of the orthographic projection of the pixel opening 21 on the substrate 1 is greater than or equal to 1 μm and less than or equal to 1.5 μm. For example, the minimum distance L1 may be 1 μm, 1.1 μm, 1.2 μm, 1.3 μm, 1.4 μm, or 1.5 μm. The proper setting of the minimum distance L1 can further reduce the reflectivity of the ambient light at the first light-emitting unit without affecting the light extraction of the first light-emitting unit.

The minimum distance L2 between the orthographic projection on the substrate 1 of the side facing the isolation opening 8 of the light shielding portion 131 corresponding to the second light-emitting unit and the edge of the orthographic projection of the pixel opening 21 on the substrate 1 is greater than or equal to 1.5 μm and less than or equal to 2 μm. For example, the minimum distance L2 may be 1.5 μm, 1.7 μm, 1.9 μm, or 2 μm. The proper setting of the minimum distance L2 can further reduce the reflectivity of the ambient light at the second light-emitting unit without affecting the light extraction of the second light-emitting unit.

In some embodiments, the minimum distance L3 between the orthographic projection on the substrate 1 of the side facing the isolation opening 8 of the light shielding portion 131 corresponding to the third light-emitting unit and the edge of the orthographic projection of the pixel opening 21 on the substrate 1 is greater than or equal to 1 μm and less than or equal to 1.5 μm. For example, the minimum distance L3 may be 1 μm, 1.1 μm, 1.2 μm, 1.3 μm, 1.4 μm, or 1.5 μm. The proper setting of the minimum distance L3 can further reduce the reflectivity of the ambient light at the third light-emitting unit without affecting the light extraction of the third light-emitting unit.

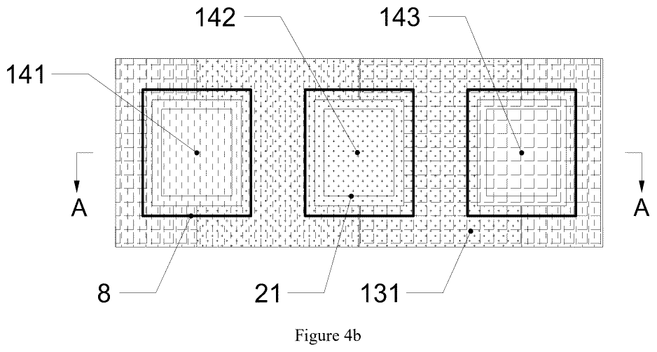

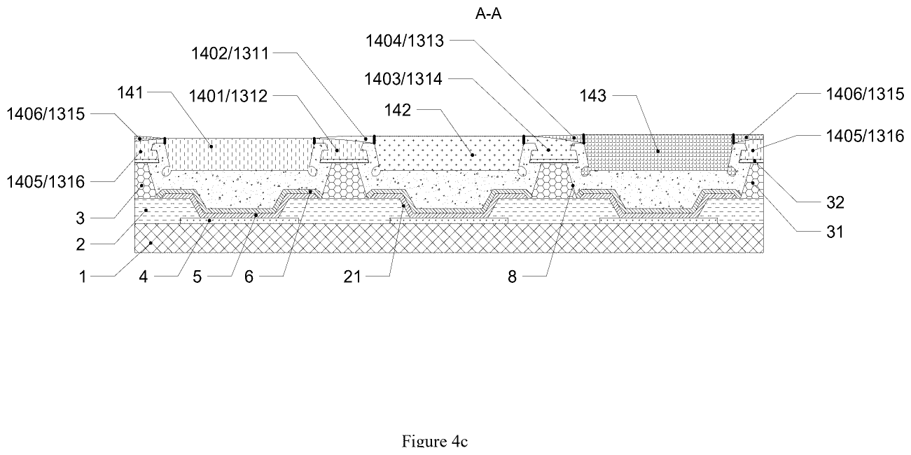

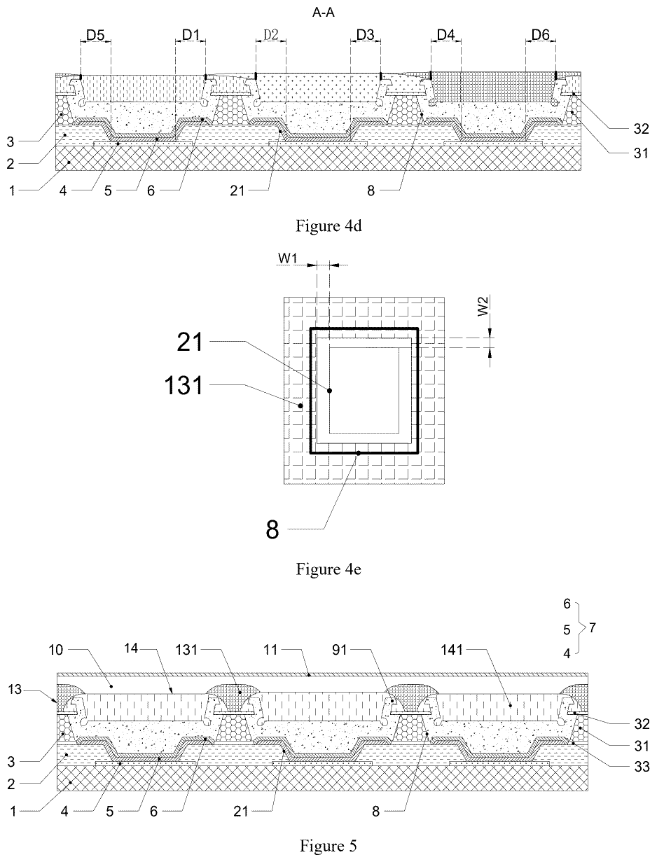

In some embodiments, referring to FIG. 4a, the light shielding portion 131 is located on a side, close to the isolation structure, of a line connecting an edge of the pixel opening 21 and an edge of the isolation opening 8.

The line connecting the edge of the pixel opening 21 and the edge of the isolation opening 8 is shown as a bold line in FIG. 4a, and the light shielding portion 131 is disposed on the side, close to the isolation structure, of the line connecting the edge of the pixel opening 21 and the edge of the isolation opening 8. That is, the light shielding portion 131 does not overlap the area of the line connecting the edge of the pixel opening 21 and the edge of the isolation opening 8, and the light shielding portion 131 is less likely to shield the light at the maximum viewing angle from the light-emitting unit 7, and the light shielding portion 131 does not shield the light emitted by the light-emitting unit 7 as much as possible while ensuring the absorption effect on the ambient light, and the light extraction efficiency of the light-emitting unit 7 can thus be further improved.

In some embodiments, referring again to FIG. 4a, the isolation structure 3 and the pixel defining layer 2 have a pixel isolation cross-section in any direction extending along a centerline of the light-emitting unit 7, the pixel defining layer 2 has a first edge point on either side of the pixel isolation cross-section close to the isolation opening 8, the isolation structure 3 has a second edge point on either side of the pixel isolation cross-section close to the isolation opening 8, an edge line 17 is formed between the first edge point and the second edge point on the same side of the pixel isolation cross-section, and an edge of the light shielding portion 131 is located on a side of the edge line 17 away from the isolation opening 8. In this way, the light shielding portion 131 is less likely to shield the light at the maximum viewing angle from the light-emitting unit 7, and the light shielding portion 131 does not shield the light emitted by the light-emitting unit 7 as much as possible while ensuring the absorption effect on the ambient light, and the light extraction efficiency of the light-emitting unit 7 can thus be further improved.

In some embodiments, the edge lines 17 of the isolation cross-section include a first sub-edge line 171 and a second sub-edge line 172 disposed on different sides of the isolation cross-section, and the light shielding portion 131 located on a side of the isolation cross-section facing away from the substrate 1 is located within a range of a pattern formed by the first sub-edge line 171, the second sub-edge line 172 and the isolation cross-section. In this way, the light shielding portion 131 is further less likely to shield the light at the maximum viewing angle from the light-emitting unit 7, and the light shielding portion 131 does not shield the light emitted by the light-emitting unit 7 as much as possible while ensuring the absorption effect on the ambient light, and the light extraction efficiency of the light-emitting unit 7 can thus be further improved.

In some embodiments, referring again to FIG. 4a, in a thickness direction of the substrate 1, a thickness H2 of the filter portion 141 for the second light-emitting unit is greater than a thickness H1 of the filter portion 141 for the first light-emitting unit and a thickness H3 of the filter portion 141 for the third light-emitting unit.

Optionally, the thickness H1 of the filter portion 141 located on the side of the first light-emitting unit facing away from the substrate 1 is greater than the thickness H3 of the filter portion 141 located on the side of the third light-emitting unit facing away from the substrate 1.

The human eye is more sensitive to green than red and blue. In this embodiment, by setting the thickness H2 to be greater than the thickness H1 and the thickness H3, it is possible to reduce the reflection of the ambient light by the filter portion 141 for the second light-emitting unit, and thus to further improve the display effect of the display panel.

Specifically, in the thickness direction of the substrate 1, the thickness of the filter portion 141 is greater than or equal to 1 μm and less than or equal to 5 μm. For example, the thickness H1 or the thickness H2 or the thickness H3 may be 1 μm, 2 μm, 3 μm, 4 μm, or 5 μm. By properly setting the thickness of the filter portion 141, it is possible to improve the filter effect of the filter portion 141 without the need for increasing the thickness of the display panel.

In some embodiments, referring again to FIG. 4a, in the thickness direction of the substrate 1, a thickness H4 of the light shielding portion 131 is greater than or equal to 1 μm and less than or equal to 3 μm. For example, the thickness H4 may be 1 μm, 1.5 μm, 2 μm, 2.5 μm, 3 μm, 3.5 μm, or 4 μm. By properly setting the thickness H4 of the light shielding portion 131, it is possible to improve the absorption effect of the light shielding portion 131 on the ambient light without the need for increasing the thickness of the display panel.

In some embodiments, referring again to FIG. 4a, a side of the encapsulation unit 91 away from the substrate 1 is in contact with a side of the filter portion 141 close to the substrate 1.

By configuring the side of the encapsulation unit 91 away from the substrate 1 to be in contact with the side of the filter portion 141 adjacent to the substrate 1 in this embodiment, it is possible to reduce the distance between the filter portion 141 and the light-emitting unit 7, and thus to further improve the light extraction efficiency of the light-emitting unit 7.

In some embodiments, the encapsulation units 91 are spaced apart on the side of the isolation structure 3 away from the substrate 1, at least part of the light shielding portion 131 is located between two adjacent encapsulation units 91, and there is a gap between the encapsulation unit 91 located on the side of the isolation structure 3 away from the substrate 1 and the side of the isolation structure 3 away from the substrate 1. An orthographic projection of the encapsulation unit 91 on the substrate 1 covers the orthographic projection of the isolation opening 8 on the substrate 1 and covers part of the orthographic projection of the isolation structure 3 on the substrate 1.

In the process of patterning the light-emitting units 7, the first encapsulation layer 9 is disconnected at the isolation structure 3 to form the encapsulation units 91, and the encapsulation units 91 can encapsulate the corresponding light-emitting units 7 completely separately, and the display characteristics of the display panel can be improved.

In some embodiments, the filter portion 141 and/or the light shielding portion 131 fills at least part of the gap, and the stability of the filter portion 141 and/or the light shielding portion 131 can be improved.

In some embodiments, referring to FIGS. 4b, 4c and 4d, the filter portions include a first filter portion 1411, a second filter portion 1412 and a third filter portion 1413. The first filter portion 1411 is located on a side of the first light-emitting unit away from the substrate 1, the second filter portion 1412 is located on a side of the second light-emitting unit away from the substrate 1, and the third filter portion 1413 is located on a side of the third light-emitting unit away from the substrate 1. A color of the first filter portion 1411 is the same as the light-emitting color of the first light-emitting unit, a color of the second filter portion 1412 is the same as the light-emitting color of the second light-emitting unit, and a color of the third filter portion 1413 is the same as the light-emitting color of the third light-emitting unit.

In this embodiment, a minimum distance between an orthographic projection on the substrate 1 of a side of the light shielding portion facing the isolation opening 8 and the edge of the orthographic projection of the pixel opening 21 on the substrate 1 is greater than or equal to 0 and less than or equal to 8 μm. For example, the minimum distance may be 0, 1 μm, 2 μm, 3 μm, 4 μm, 5 μm, 6 μm, 7 μm, or 8 μm.

Further, the minimum distance between the orthographic projection on the substrate 1 of the side of the light shielding portion facing the isolation opening 8 and the edge of the orthographic projection of the pixel opening 21 on the substrate 1 is greater than or equal to 1.5 μm and less than or equal to 8 μm. For example, the minimum distance may be 1.6 μm, 2 μm, 3 μm, 4 μm, or 5 μm.

The orthographic projection of the pixel opening 21 on the substrate 1 in this embodiment refers to the orthographic projection on the substrate 1 of the side of the pixel opening 21 close to the side of the substrate 1. By properly setting the minimum distance between the orthographic projection on the substrate 1 of the side of the light shielding portion facing the isolation opening 8 and the edge of the orthographic projection of the pixel opening 21 on the substrate 1, it is possible to reduce the reflectivity of the ambient light while improving the light extraction efficiency of the light-emitting unit 7, and thus to improve the display effect of the display panel.

In some embodiments, referring again to FIGS. 4b, 4c and 4d, the first filter portion 1411 includes a first filter sub-portion 1401 extending to the side of the isolation structure 3 away from the substrate 1, the first filter sub-portion 1401 being located between the first light-emitting unit and the second light-emitting unit, and the second filter portion 1412 includes a second filter sub-portion 1402 extending to a side of the first filter sub-portion 1401 away from the substrate 1. An orthographic projection of the first filter sub-portion 1401 on the substrate 1 overlaps an orthographic projection of the second filter sub-portion 1402 on the substrate 1.

Optionally, the light shielding portion includes a first light shielding sub-portion 1311 located on the side of the first filter sub-portion 1401 away from the substrate 1. The first light shielding sub-portion 1311 is located between the first light-emitting unit and the second light-emitting unit, and an orthographic projection of the first light shielding sub-portion 1311 on the substrate 1 overlaps the orthographic projection of the first filter sub-portion 1401 on the substrate 1.

Optionally, the first light shielding sub-portion 1311 corresponding to the first light-emitting unit includes the second filter sub-portion 1402.

The light of the same color as that emitted by the first light-emitting unit may be transmitted through the first filter sub-portion 1401, but cannot be transmitted through the second filter sub-portion 1402, and the second filter sub-portion 1402 may be used as the first light shielding sub-portion 1311 for the first light-emitting unit. The first light shielding sub-portion 1311 can reduce the reflectivity of the ambient light of the same color as that emitted by the first light-emitting unit. In addition, the first light shielding sub-portion 1311 may be formed while forming the second filter portion 1412, without the need for a dedicated process for forming the first light shielding sub-portion 1311, and the cost of forming the first light shielding sub-portion 1311 can be reduced.

In some embodiments, the light shielding portion includes a second light shielding sub-portion 1312 located on the side of the second filter sub-portion 1402 close to the substrate 1. The second light shielding sub-portion 1312 is located between the first light-emitting unit and the second light-emitting unit, and an orthographic projection of the second light shielding sub-portion 1312 on the substrate 1 overlaps the orthographic projection of the second filter sub-portion 1402 on the substrate 1.

Optionally, the second light shielding sub-portion 1312 corresponding to the second light-emitting unit includes the first filter sub-portion 1401.

The light of the same color as that emitted by the second light-emitting unit may be transmitted through the second filter sub-portion 1402, but cannot be transmitted through the first filter sub-portion 1401, and the first filter sub-portion 1401 may be used as the second light shielding sub-portion 1312 for the second light-emitting unit. The second light shielding sub-portion 1312 can reduce the reflectivity of the ambient light of the same color as that emitted by the second light-emitting unit. In addition, the second light shielding sub-portion 1312 may be formed while forming the first filter portion 1411, without the need for a dedicated process for forming the second light shielding sub-portion 1312, and the cost of forming the second light shielding sub-portion 1312 can be reduced.

In some embodiments, the second filter portion 1412 includes a third filter sub-portion 1403 extending to the side of the isolation structure 3 away from the substrate 1. The third filter sub-portion 1403 is located between the second light-emitting unit and the third light-emitting unit, and the third filter portion 1413 includes a fourth filter sub-portion 1404 extending to a side of the third filter sub-portion 1403 away from the substrate 1. An orthographic projection of the third filter sub-portion 1403 on the substrate 1 overlaps an orthographic projection of the fourth filter sub-portion 1404 on the substrate 1.

Optionally, the light shielding portion includes a third light shielding sub-portion 1313 located on the side of the third filter sub-portion 1403 away from the substrate 1. The third light shielding sub-portion 1313 is located between the second light-emitting unit and the third light-emitting unit, and an orthographic projection of the third light shielding sub-portion 1313 on the substrate 1 overlaps the orthographic projection of the third filter sub-portion 1403 on the substrate 1.

Optionally, the third light shielding sub-portion 1313 corresponding to the second light-emitting unit includes the fourth filter sub-portion 1404.

The light of the same color as that emitted by the second light-emitting unit may be transmitted through the third filter sub-portion 1403, but cannot be transmitted through the fourth filter sub-portion 1404, and the fourth filter sub-portion 1404 may be used as the third light shielding sub-portion 1313 for the second light-emitting unit. The third light shielding sub-portion 1313 can reduce the reflectivity of the ambient light of the same color as that emitted by the second light-emitting unit. In addition, the third light shielding sub-portion 1313 may be formed while forming the third filter portion 1413, without the need for a dedicated process for forming the third light shielding sub-portion 1313, and the cost of forming the third light shielding sub-portion 1313 can be reduced.

In some embodiments, the light shielding portion includes a fourth light shielding sub-portion 1314 located on a side of the fourth filter sub-portion 1404 close to the substrate 1. The fourth light shielding sub-portion 1314 is located between the second light-emitting unit and the third light-emitting unit, and an orthographic projection of the fourth light shielding sub-portion 1314 on the substrate 1 overlaps the orthographic projection of the fourth filter sub-portion 1404 on the substrate 1.

Optionally, the fourth light shielding sub-portion 1314 corresponding to the third light-emitting unit includes the third filter sub-portion 1403.

The light of the same color as that emitted by the third light-emitting unit may be transmitted through the fourth filter sub-portion 1404, but cannot be transmitted through the third filter sub-portion 1403, and the third filter sub-portion 1403 may be used as the fourth light shielding sub-portion 1314 for the third light-emitting unit. The fourth light shielding sub-portion 1314 can reduce the reflectivity of the ambient light of the same color as that emitted by the third light-emitting unit. In addition, the fourth light shielding sub-portion 1314 may be formed while forming the second filter portion 1412, without the need for a dedicated process for forming the fourth light shielding sub-portion 1314, and the cost of forming the fourth light shielding sub-portion 1314 can be reduced.

In some embodiments, the first filter portion 1411 further includes a fifth filter sub-portion 1405 extending to the side of the isolation structure 3 away from the substrate 1. The fifth filter sub-portion 1405 is located between the first light-emitting unit and the third light-emitting unit, and the third filter portion 1413 includes a sixth filter sub-portion 1406 extending to a side of the fifth filter sub-portion 1405 away from the substrate 1. An orthographic projection of the fifth filter sub-portion 1405 on the substrate 1 overlaps an orthographic projection of the sixth filter sub-portion 1406 on the substrate 1.

In some embodiments, the light shielding portion includes a fifth light shielding sub-portion 1315 located on the side of the fifth filter sub-portion 1405 away from the substrate 1. The fifth light shielding sub-portion 1315 is located between the first light-emitting unit and the third light-emitting unit, and an orthographic projection of the fifth light shielding sub-portion 1315 on the substrate 1 overlaps the orthographic projection of the fifth filter sub-portion 1405 on the substrate 1.

In some embodiments, the fifth light shielding sub-portion 1315 corresponding to the first light-emitting unit includes the sixth filter sub-portion 1406.

The light of the same color as that emitted by the first light-emitting unit may be transmitted through the fifth filter sub-portion 1405, but cannot be transmitted through the sixth filter sub-portion 1406, and the sixth filter sub-portion 1406 may be used as the fifth light shielding sub-portion 1315 for the first light-emitting unit. The fifth light shielding sub-portion 1315 can reduce the reflectivity of the ambient light of the same color as that emitted by the first light-emitting unit. In addition, the fifth light shielding sub-portion 1315 may be formed while forming the third filter portion 1413, without the need for a dedicated process for forming the fifth light shielding sub-portion 1315, and the cost of forming the fifth light shielding sub-portion 1315 can be reduced.

In some embodiments, the light shielding portion includes a sixth light shielding sub-portion 1316 located on a side of the sixth filter sub-portion 1406 close to the substrate 1. The sixth light shielding sub-portion 1316 is located between the first light-emitting unit and the third light-emitting unit, and an orthographic projection of the sixth light shielding sub-portion 1316 on the substrate 1 overlaps the orthographic projection of the sixth filter sub-portion 1406 on the substrate 1.

In some embodiments, the sixth light shielding sub-portion 1316 corresponding to the third light-emitting unit includes the fifth filter sub-portion 1405.

The light of the same color as that emitted by the third light-emitting unit may be transmitted through the sixth filter sub-portion 1406, but cannot be transmitted through the fifth filter sub-portion 1405, and the fifth filter sub-portion 1405 may be used as the sixth light shielding sub-portion 1316 for the third light-emitting unit. The sixth light shielding sub-portion 1316 can reduce the reflectivity of the ambient light of the same color as that emitted by the third light-emitting unit. In addition, the sixth light shielding sub-portion 1316 may be formed while forming the first filter portion 1411, without the need for a dedicated process for forming the sixth light shielding sub-portion 1316, and the cost of forming the sixth light shielding sub-portion 1316 can be reduced.

In some embodiments, referring again to FIGS. 4b, 4c and 4d, a minimum distance D1 between the orthographic projection on the substrate 1 of a side of the first light shielding sub-portion 1311 facing the first light-emitting unit and an edge of the orthographic projection on the substrate 1 of the pixel opening 21 for the first light-emitting unit is greater than or equal to 0 and less than or equal to 5 μm. For example, the minimum distance D1 may be 0, 1 μm, 2 μm, 3 μm, 4 μm, or 5 μm. By properly setting the minimum distance D1, it is possible to reduce the reflectivity of the ambient light of the same color as that emitted by the first light-emitting unit while improving the light extraction efficiency of the first light-emitting unit, and thus to improve the display effect of the display panel.

In some embodiments, the display panel further includes a pixel defining layer 2 located on one side of the substrate 1. The isolation structure 3 is located on a side of the pixel defining layer 2 away from the substrate 1. The pixel defining layer 2 includes a plurality of pixel openings 21 disposed at intervals. A minimum distance D2 between an orthographic projection on the substrate 1 of a side of the second light shielding sub-portion 1312 facing the second light-emitting unit and an edge of the orthographic projection on the substrate 1 of the pixel opening 21 for the second light-emitting unit is greater than or equal to 3 μm and less than or equal to 8 μm. For example, the minimum distance D2 may be 3 μm, 4 μm, 5 μm, 6 μm, 7 μm, or 8 μm. By properly setting the minimum distance D2, it is possible to reduce the reflectivity of the ambient light of the same color as that emitted by the second light-emitting unit while improving the light extraction efficiency of the second light-emitting unit, and thus to improve the display effect of the display panel.

In some embodiments, a minimum distance D3 between an orthographic projection on the substrate 1 of a side of the third light shielding sub-portion 1313 facing the second light-emitting unit and the edge of the orthographic projection on the substrate 1 of the pixel opening 21 for the second light-emitting unit is greater than or equal to 3 μm and less than or equal to 8 μm. For example, the minimum distance D3 may be 3 μm, 4 μm, 5 μm, 6 μm, 7 μm, or 8 μm. By properly setting the minimum distance D3, it is possible to reduce the reflectivity of the ambient light of the same color as that emitted by the third light-emitting unit while improving the light extraction efficiency of the third light-emitting unit, and thus to improve the display effect of the display panel.

In some embodiments, a minimum distance D4 between an orthographic projection on the substrate 1 of a side of the fourth light shielding sub-portion b 1314 facing the third light-emitting unit and an edge of the orthographic projection on the substrate 1 of the pixel opening 21 for the third light-emitting unit is greater than or equal to 0 and less than or equal to 5 μm. For example, the minimum distance D4 may be 0, 1 μm, 2 μm, 3 μm, 4 μm, or 5 μm. By properly setting the minimum distance D4, it is possible to reduce the reflectivity of the ambient light of the same color as that emitted by the third light-emitting unit while improving the light extraction efficiency of the third light-emitting unit, and thus to improve the display effect of the display panel.

In some embodiments, a minimum distance D5 between an orthographic projection on the substrate 1 of a side of the fifth light shielding sub-portion 1315 facing the first light-emitting unit and the edge of the orthographic projection on the substrate 1 of the pixel opening 21 for the first light-emitting unit is greater than or equal to 0 and less than or equal to 5 μm. For example, the minimum distance D5 may be 0, 1 μm, 2 μm, 3 μm, 4 μm, or 5 μm. By properly setting the minimum distance D5, it is possible to reduce the reflectivity of the ambient light of the same color as that emitted by the first light-emitting unit while improving the light extraction efficiency of the first light-emitting unit, and thus to improve the display effect of the display panel.

In some embodiments, a minimum distance D6 between an orthographic projection on the substrate 1 of a side of the sixth light shielding sub-portion 1316 facing the third light-emitting unit and the edge of the orthographic projection on the substrate 1 of the pixel opening 21 for the third light-emitting unit is greater than or equal to 0 and less than or equal to 5 μm. For example, the minimum distance D6 may be 0, 1 μm, 2 μm, 3 μm, 4 μm, or 5 μm. By properly setting the minimum distance D6, it is possible to reduce the reflectivity of the ambient light of the same color as that emitted by the third light-emitting unit while improving the light extraction efficiency of the third light-emitting unit, and thus to improve the display effect of the display panel.

In some embodiments, referring to FIG. 4e, the orthographic projection of the pixel opening 21 on the substrate 1 includes a first edge 211 and a second edge 212 connected to each other. An extension length of the first edge 211 is greater than an extension length of the second edge 212. A minimum distance W1 between the orthographic projection on the substrate 1 of the side of the light shielding portion close to the isolation opening 8 and the first edge 211 is greater than a minimum distance W2 between the orthographic projection on the substrate 1 of the side of the light shielding portion close to the isolation opening 8 and the second edge 212.

The minimum distance W1 is greater than the minimum distance W2, and therefore the light shielding portion shields a smaller amount of light from the light-emitting unit 7 in the direction of the first edge 211. Since the extension length of the first edge 211 is greater than the extension length of the second edge 212, it is possible to improve the overall light extraction efficiency of the light-emitting unit 7, and thus to improve the display effect of the display panel.

Optionally, the minimum distance W1 between the orthographic projection on the substrate 1 of the side of the light shielding portion close to the isolation opening 8 and the first edge is greater than or equal to 2.5 μm and less than or equal to 6.5 μm. For example, the minimum distance W1 may be 2.5 μm, 3 μm, 4 μm, 5 μm, 6 μm, or 6.5 μm.

Optionally, the minimum distance W2 between the orthographic projection on the substrate 1 of the side of the light shielding portion close to the isolation opening 8 and the second edge is greater than or equal to 1 μm and less than or equal to 5 μm. For example, the minimum distance W2 may be 1 μm, 2 μm, 3 μm, 4 μm, or 5 μm.

By properly setting the minimum distance W1 and the minimum distance W2, it is possible to reduce the reflectivity of the ambient light while improving the light extraction efficiency of the light-emitting unit 7, and thus to improve the display effect of the display panel. In some embodiments, referring to FIG. 5, the display panel further includes a second encapsulation layer 10 located on the side of the filter layer 14 and the light shielding layer 13 away from the substrate 1, and a third encapsulation layer 11 located on a side of the second encapsulation layer 10 away from the substrate 1. Materials of the encapsulation unit 91 and the third encapsulation layer 11 each include an inorganic material, and a material of the second encapsulation layer 10 includes an organic material.

For example, the encapsulation unit 91 and the third encapsulation layer 11 may be formed by means of chemical vapor deposition (CVD), and the second encapsulation layer 10 may be formed by means of ink-jet printing (IJP). The second encapsulation layer 10 and the third encapsulation layer 11 can play a better encapsulating effect on the light-emitting unit 7, and the encapsulation quality of the display panel can be further improved.

In some embodiments, referring again to FIG. 4a, the isolation structure 3 includes a first isolation portion 31 and a second isolation portion 32 sequentially stacked in the direction away from the substrate 1. An orthographic projection on the substrate 1 of a side of the first isolation portion 31 away from the substrate 1 is located within an orthographic projection of the second isolation portion 32 on the substrate 1.

Since the second isolation portion 32 is located on the side of the first isolation portion 31 away from the substrate 1, and a transverse width of the second isolation portion 32 is greater than a transverse width of the first isolation portion 31 in a plane parallel to the substrate 1, the second isolation portion 32 disconnects the light-emitting functional layer from the second electrode layer at the isolation structure 3. In this way, the isolation structure 3 formed by the first isolation portion 31 and the second isolation portion 32 can make it easier to encapsulate each light-emitting unit 7 independently, and the encapsulation yield of the display panel can be improved.

In some embodiments, referring again to FIG. 4a, the second electrode 6 is electrically connected to the first isolation portion 31. The first isolation portion 31 includes a conductive material, and the second electrode 6 corresponding to the light-emitting unit 7 extends to come into contact with a side wall of the first isolation portion 31, to electrically connect the second electrode 6 corresponding to the light-emitting unit 7 and the first isolation portion 31.

Referring again to FIG. 5, the isolation structure 3 further includes a third isolation portion 33 located on a side of the first isolation portion 31 facing the substrate 1, and the second electrode 6 is electrically connected to the third isolation portion 33.

The third isolation portion 33 includes a conductive material, and the second electrode 6 corresponding to the light-emitting unit 7 extends to come into contact with a side wall of the third isolation portion 33, to electrically connect the second electrode 6 corresponding to the light-emitting unit 7 to the third isolation portion 33.

Specifically, a material of the third isolation portion 33 includes a molybdenum metal; and/or a material of the first isolation portion 31 includes an aluminum metal; and/or a material of the second isolation portion 32 includes a titanium metal. Thus, when the isolation structure 3 separates the second electrode layer into the second electrodes 6, the second electrodes 6 are more easily electrically connected to the first isolation portion 31 and/or the third isolation portion 33.

In some embodiments, referring to FIG. 4a, the present application further provides a display panel, including a substrate 1, a pixel defining layer 2, an isolation structure 3, light-emitting units 7, encapsulation units 91, a filter layer 14, and a light shielding layer 13.

The pixel defining layer 2 is located on one side of the substrate 1, the pixel defining layer 2 includes a plurality of pixel openings 21.

The isolation structure 3 is located on one side of the substrate 1, and the isolation structure 3 encloses isolation openings 8. The light-emitting units 7 are at least partially located in the isolation openings 8. The pixel opening 21 is in communication with the isolation opening 8.

Encapsulation units 91 are located on a side of the light-emitting units 7 away from the substrate 1. A plurality of encapsulation units 91 form a first encapsulation layer 9. At least part of the encapsulation unit 91 extends from a side surface of the isolation structure 3 facing the isolation opening 8 to a side of the isolation structure 3 away from the substrate 1.

The filter layer 14 is located on the side of the encapsulation units 91 away from the substrate 1, and the filter layer 14 includes a plurality of filter portions 141 disposed at intervals. An orthographic projection of the filter portion 141 on the substrate 1 at least partially overlaps an orthographic projection of the light-emitting unit 7 on the substrate 1.

A filter color of the filter portion 141 is the same as a light-emitting color of the corresponding light-emitting unit 7, and the filter portion 141 can allows light emitted by the corresponding light-emitting unit 7 to pass through and filters out light of different colors emitted by the other light-emitting units 7. For example, the light emitted by the light-emitting unit 7 is red, and the filter portion 141 corresponding to the light-emitting unit 7 can allow the red light to pass through and filters out the light other than red light. Therefore, the filter portion 141 can improve the light extraction efficiency of the light-emitting unit 7.

The light shielding layer 13 is located on the side of the isolation structure 3 away from the substrate 1, and the light shielding layer 13 includes a plurality of light shielding portions 131 disposed at intervals. An orthographic projection of the light shielding portion 131 on the substrate 1 at least partially overlaps an orthographic projection of the isolation structure 3 on the substrate 1, part of the light shielding portion 131 extends to a side of the filter portion 141 away from the substrate 1, and the light shielding portion 131 is located outside the area of a line connecting an edge of the pixel opening 21 and an edge of the isolation opening 8. The filter portions 141 and the light shielding portions 131 are spaced apart in a direction of arrangement of the isolation openings 8.

A material of the light shielding portion 131 may include black rubber, and light emitted by the light-emitting unit 7 generally cannot pass through the light shielding portion 131. In this embodiment, the light shielding portion 131 is disposed on the side of the isolation structure 3 away from the substrate 1, and a distance between the light shielding portion 131 and the light-emitting unit 7 can be reduced. Therefore, the amount of light at a wide viewing angle from the light-emitting unit 7 that is shielded by the light shielding portion 131 can be reduced, and the amount of light extracted from the light-emitting unit 7 at a wide viewing angle can be increased.

The light shielding portion 131 can absorb the light irradiated from the outside, and reduce the reflectivity of ambient light, and the light extraction effect of the light-emitting unit 7 can be improved. In this embodiment, the light shielding portion 131 extends in the direction of the isolation opening 8, and part of the light shielding portion 131 extends to the side of the filter portion 141 away from the substrate 1, to partially overlap the light shielding portion 131 with the filter portion 141, and the absorption area of the light shielding portion 131 for the ambient light can be increased, and the reflectivity of the ambient light can thus be further reduced.

The line connecting the edge of the pixel opening 21 and the edge of the isolation opening 8 is shown as a bold line in FIG. 4a, and the light shielding portion 131 is disposed outside the area of the line connecting the edge of the pixel opening 21 and the edge of the isolation opening 8. That is, the light shielding portion 131 does not overlap the area of the line connecting the edge of the pixel opening 21 and the edge of the isolation opening 8, and the light shielding portion 131 is less likely to shield the light at the maximum viewing angle from the light-emitting unit 7, and the light shielding portion 131 does not shield the light emitted by the light-emitting unit 7 as much as possible while ensuring the absorption effect on the ambient light, and the light extraction efficiency of the light-emitting unit 7 can thus be further improved.

In some embodiments, referring to FIGS. 2 and 3, the present application further provides a display panel, including a substrate 1, a pixel defining layer 2, an isolation structure 3, light-emitting units 7, a filter layer 14, and a light shielding layer 13.

The pixel defining layer 2 is located on one side of the substrate 1, and the pixel defining layer 2 includes pixel openings 21.

The isolation structure 3 is located on one side of the substrate 1, and the isolation structure 3 encloses isolation openings 8. The light-emitting units 7 are at least partially located in the isolation openings 8. The pixel opening 21 is in communication with the isolation opening 8.

Encapsulation units 91 are located on a side of the light-emitting units 7 away from the substrate 1. A plurality of encapsulation units 91 form a first encapsulation layer 9. At least part of the encapsulation unit 91 extends from a side surface of the isolation structure 3 facing the isolation opening 8 to a side of the isolation structure 3 away from the substrate 1.

The filter layer 14 is located on the side of the encapsulation units 91 away from the substrate 1, and the filter layer 14 includes a plurality of filter portions 141 disposed at intervals. An orthographic projection of the filter portion 141 on the substrate 1 covers an orthographic projection of the light-emitting unit 7 on the substrate 1.

A filter color of the filter portion 141 is the same as a light-emitting color of the corresponding light-emitting unit 7, and the filter portion 141 can allows light emitted by the corresponding light-emitting unit 7 to pass through and filters out light of different colors emitted by the other light-emitting units 7. For example, the light emitted by the light-emitting unit 7 is red, and the filter portion 141 corresponding to the light-emitting unit 7 can allow the red light to pass through and filters out the light other than red light. Therefore, the filter portion 141 can improve the light extraction efficiency of the light-emitting unit 7.

The light shielding layer 13 is located on the side of the isolation structure 3 away from the substrate 1, and the light shielding layer 13 includes a plurality of light shielding portions 131 disposed at intervals. An orthographic projection of the light shielding portion 131 on the substrate 1 at least partially overlaps an orthographic projection of the isolation structure 3 on the substrate 1, and part of the light shielding portion 131 extends to a side of the filter portion 141 away from the substrate 1. The filter portions 141 and the light shielding portions 131 are spaced apart in a direction of arrangement of the isolation openings 8.

An edge of an orthographic projection on the substrate 1 of a side of the light shielding portion 131 close to the isolation opening 8 is located between an edge of the orthographic projection of the pixel opening 21 on the substrate 1 and an edge of the orthographic projection of the isolation opening 8 on the substrate 1.

A material of the light shielding portion 131 may include black rubber, and light emitted by the light-emitting unit 7 generally cannot pass through the light shielding portion 131. In this embodiment, the light shielding portion 131 is disposed on the side of the isolation structure 3 away from the substrate 1, and a distance between the light shielding portion 131 and the light-emitting unit 7 can be reduced. Therefore, the amount of light at a wide viewing angle from the light-emitting unit 7 that is shielded by the light shielding portion 131 can be reduced, and the amount of light extracted from the light-emitting unit 7 at a wide viewing angle can be increased.

The light shielding portion 131 can absorb the light irradiated from the outside, and reduce the reflectivity of ambient light, and the light extraction effect of the light-emitting unit 7 can be improved. In this embodiment, the light shielding portion 131 extends in the direction of the isolation opening 8, and part of the light shielding portion 131 extends to the side of the filter portion 141 away from the substrate 1, to partially overlap the light shielding portion 131 with the filter portion 141, and the absorption area of the light shielding portion 131 for the ambient light can be increased, and the reflectivity of the ambient light can thus be further reduced.

The pixel opening 21 in this embodiment refers to an area formed by enclosing a side of the pixel opening 21 close to the substrate 1, the isolation opening 8 refers to an opening formed by enclosing the side of the isolation structure 3 away from the substrate 1, and the light shielding portion 131 extends in the direction of the isolation opening 8 between the pixel opening 21 and the isolation opening 8, and the absorption effect of the light shielding portion 131 on the ambient light can be further improved, to further reduce the reflectivity of the ambient light, the influence of the ambient light on the light emitted by the light-emitting unit 7 can thus be further reduced, and the display effect of the light-emitting unit 7 can thus be further improved.

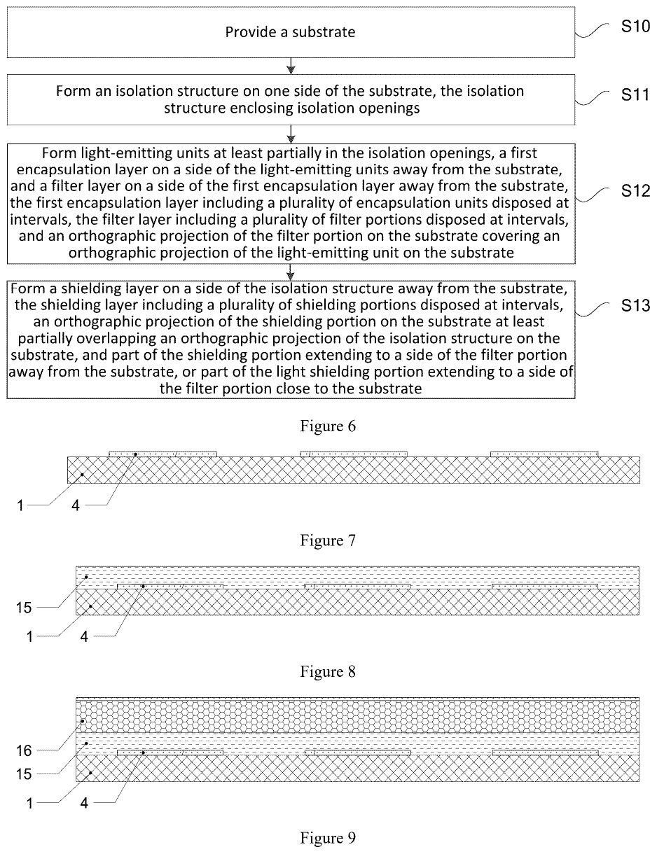

In some embodiments, referring to FIG. 6, the present application further provides a method for preparing a display panel, the method including the following steps.
In step S10, a substrate 1 is provided.
In step S11, an isolation structure 3 is formed on one side of the substrate 1, the isolation structure 3 enclosing isolation openings 8.
In step S12, light-emitting units 7 are at least partially formed in the isolation openings 8, an encapsulation layer 9 are formed on a side of the light-emitting units 7 away from the substrate 1, and a filter layer 14 is formed on a side of the encapsulation layer 9 away from the substrate 1, the encapsulation layer 9 including a plurality of encapsulation units 91 disposed at intervals, the filter layer 14 including a plurality of filter portions 141 disposed at intervals, and an orthographic projection of the filter portion 141 on the substrate 1 at least partially overlapping an orthographic projection of the light-emitting unit 7 on the substrate 1.

Referring to FIG. 7, a first electrode layer is formed on one side of the substrate 1, the first electrode layer including a plurality of first electrodes 4 disposed at intervals.

Referring to FIG. 8, a pixel defining material layer 15 is formed on a side of the first electrode layer away from the substrate 1.

Referring to FIG. 9, an isolation material layer 16 is formed on a side of the pixel defining material layer 15 away from the substrate 1.

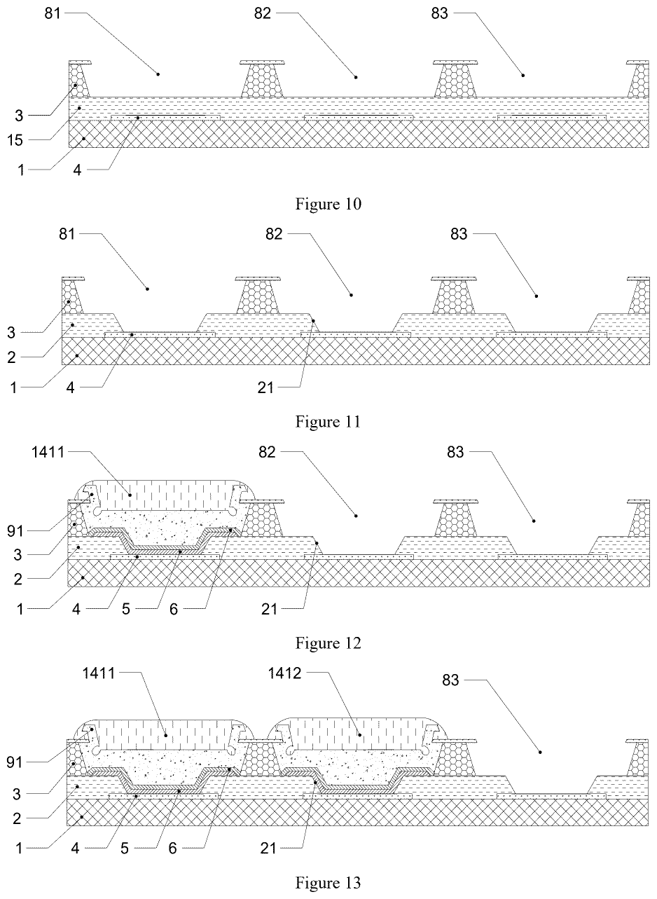

Referring to FIG. 10, the isolation material layer 16 is patterned to form the isolation structure 3.

Referring to FIG. 11, the pixel defining material layer 15 is patterned to form the pixel defining layer 2. The pixel defining layer 2 includes pixel openings 21 at least partially exposing the first electrodes 4. The orthographic projection of the pixel opening 21 on the substrate 1 is located within the orthographic projection of the isolation opening 8 on the substrate 1.
In step S13, a light shielding layer 13 is formed on a side of the isolation structure 3 away from the substrate 1. The light shielding layer 13 includes a plurality of light shielding portions 131 disposed at intervals. An orthographic projection of the light shielding portion 131 on the substrate 1 at least partially overlaps an orthographic projection of the isolation structure 3 on the substrate 1, and the orthographic projection of the light shielding portion 131 on the substrate 1 at least partially overlaps the orthographic projection of the filter portion 141 on the substrate 1.

Referring again to FIG. 2, after the filter layer 14 is formed, the light shielding layer 13 is formed on the side of the isolation structure 3 away from the substrate 1.

In the display panel formed by the above method, by disposing the filter portion 141 on the side of the encapsulation layer 9 away from the substrate 1, it is possible to reduce the distance between the filter portion 141 and the light-emitting unit 7, and thus to further improve the light extraction efficiency of the light-emitting unit 7.

The light shielding layer 13 is located on the side of the isolation structure 3 away from the substrate 1, and the light shielding layer 13 includes a plurality of light shielding portions 131 disposed at intervals. An orthographic projection of the light shielding portion 131 on the substrate 1 at least partially overlaps an orthographic projection of the isolation structure 3 on the substrate 1, and part of the light shielding portion 131 extends to a side of the filter portion 141 away from the substrate 1. The filter portions 141 and the light shielding portions 131 are spaced apart in a direction of arrangement of the isolation openings 8.

A material of the light shielding portion 131 may include black rubber, and light emitted by the light-emitting unit 7 generally cannot pass through the light shielding portion 131. In this embodiment, the light shielding portion 131 is disposed on the side of the isolation structure 3 away from the substrate 1, and a distance between the light shielding portion 131 and the light-emitting unit 7 can be reduced. Therefore, the amount of light at a wide viewing angle from the light-emitting unit 7 that is shielded by the light shielding portion 131 can be reduced, and the amount of light extracted from the light-emitting unit 7 at a wide viewing angle can be increased.

The light shielding portion 131 can absorb the light irradiated from the outside, and reduce the reflectivity of ambient light, and the light extraction effect of the light-emitting unit 7 can be improved. In this embodiment, the light shielding portion 131 extends in the direction of the isolation opening 8, and part of the light shielding portion 131 extends to the side of the filter portion 141 away from the substrate 1, to partially overlap the light shielding portion 131 with the filter portion 141, and the absorption area of the light shielding portion 131 for the ambient light can be increased, and the reflectivity of the ambient light can thus be further reduced.

The isolation openings 8 include a first isolation opening 81, a second isolation opening 82, and a third isolation opening 83, the light-emitting units 7 include a first light-emitting unit, a second light-emitting unit, and a third light-emitting unit, and the filter layer 14 includes a first filter portion 1411, a second filter portion 1412, and a third filter portion 1413. A filter color of the first filter portion 1411 is the same as a light-emitting color of the first light-emitting unit, a filter color of the second filter portion 1412 is the same as a light-emitting color of the second light-emitting unit, and a filter color of the third filter portion 1413 is the same as a light-emitting color of the third light-emitting unit.

The step S12 of forming light-emitting units 7 at least partially in the isolation openings 8, an encapsulation layer 9 on a side of the light-emitting units 7 away from the substrate 1, and a filter layer 14 on a side of the encapsulation layer 9 away from the substrate 1 has the following two embodiments.

In the first implementation, referring to FIG. 12, the first light-emitting unit is formed in the first isolation opening 81, the encapsulation unit 91 is formed on a side of the first light-emitting unit away from the substrate 1, and the first filter portion 1411 is formed on a side away from the substrate 1 of the encapsulation unit 91 for the first light-emitting unit. An orthographic projection of the first filter portion 1411 on the substrate 1 covers an orthographic projection of the first light-emitting unit on the substrate 1.

Referring to FIG. 13, the second light-emitting unit is formed in the second isolation opening 82, the encapsulation unit 91 is formed on a side of the second light-emitting unit away from the substrate 1, and the second filter portion 1412 is formed on a side away from the substrate 1 of the encapsulation unit 91 for the second light-emitting unit. An orthographic projection of the second filter portion 1412 on the substrate 1 covers an orthographic projection of the second light-emitting unit on the substrate 1.

Since the first filter portion 1411 is formed on the side away from the substrate 1 of the encapsulation unit 91 for the first light-emitting unit before the second light-emitting unit is formed, during the process of forming the second light-emitting unit, the first filter portion 1411 can protect the first light-emitting unit and the encapsulation unit 91 for the first light-emitting unit, and it is less likely to damage the encapsulation unit 91 for the first light-emitting unit, thereby improving the encapsulation effect of the first light-emitting unit.

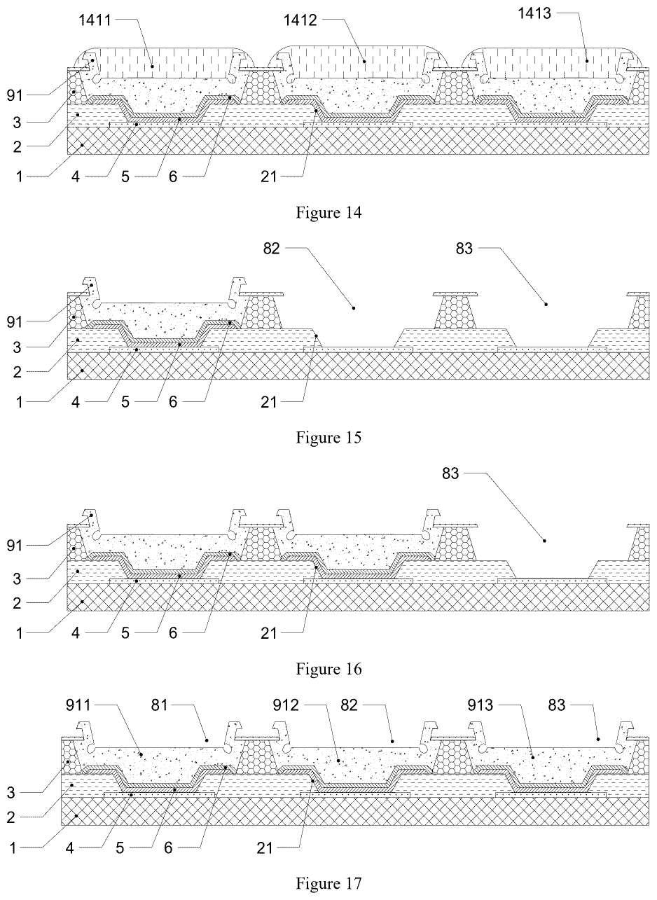

Referring to FIG. 14, the third light-emitting unit is formed in the third isolation opening 83, the encapsulation unit 91 is formed on a side of the third light-emitting unit away from the substrate 1, and the third filter portion 1413 is formed on a side away from the substrate 1 of the encapsulation unit 91 for the third light-emitting unit. An orthographic projection of the third filter portion 1413 on the substrate 1 covers an orthographic projection of the third light-emitting unit on the substrate 1.

In this embodiment, since the first filter portion 1411 is formed on the side away from the substrate 1 of the encapsulation unit 91 for the first light-emitting unit and the second filter portion 1412 is formed on the side away from the substrate 1 of the encapsulation unit 91 for the second light-emitting unit before the third light-emitting unit is formed, during the process of forming the third light-emitting unit, the first filter portion 1411 can protect the first light-emitting unit and the encapsulation unit 91 for the first light-emitting unit, and the second filter portion 1412 can protect the second light-emitting unit and the encapsulation unit 91 for the second light-emitting unit, and it is less likely to damage the encapsulation units 91 for the first light-emitting unit and the second light-emitting unit, thereby improving the encapsulation effect of the first light-emitting unit and the second light-emitting unit.

In the second implementation, referring to FIG. 15, the first light-emitting unit is formed in the first isolation opening 81, and the encapsulation unit 91 is formed on the side of the first light-emitting unit away from the substrate 1.

Referring to FIG. 16, the second light-emitting unit is formed in the second isolation opening 82, and the encapsulation unit 91 is formed on the side of the second light-emitting unit away from the substrate 1.

Referring to FIG. 17, the third light-emitting unit is formed in the third isolation opening 83, and the encapsulation unit 91 is formed on the side of the third light-emitting unit away from the substrate 1.

Referring again to FIG. 14, the filter layer 14 is formed on the side of the encapsulation units 91 away from the substrate 1. The filter layer 14 includes the first filter portion 1411, the second filter portion 1412, and the third filter portion 1413. The orthographic projection of the first filter portion 1411 on the substrate 1 covers the orthographic projection of the first light-emitting unit on the substrate 1, the orthographic projection of the second filter portion 1412 on the substrate 1 covers the orthographic projection of the second light-emitting unit on the substrate 1, and the orthographic projection of the third filter portion 1413 on the substrate 1 covers the orthographic projection of the third light-emitting unit on the substrate 1.

In this embodiment, the first light-emitting unit, the second light-emitting unit, the third light-emitting unit, and the corresponding encapsulation units 91 are formed first, and the first filter portion 1411, the second filter portion 1412, and the third filter portion 1413 are then formed in sequence. In this way, the number of times the filter layer 14 is formed can be reduced, thereby improving the preparation effect and reducing the preparation cost of the display panel.

In some embodiments, after the step of forming a light shielding layer 13 on a side of the isolation structure 3 away from the substrate 1, the method further includes the following steps.

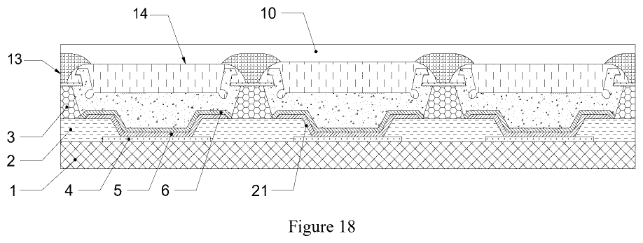

Referring to FIG. 18, a second encapsulation layer 10 is formed on a side of the filter layer 14 and the light shielding layer 13 away from the substrate 1.

Referring again to FIG. 5, a third encapsulation layer 11 is formed on a side of the second encapsulation layer 10 away from the substrate 1.

The filter layer 14 and the light shielding layer 13 formed by the above method are located between the encapsulation units 91 and the second encapsulation layer 10, and the encapsulation effect of the light-emitting unit 7 can be further improved by forming the second encapsulation layer 10 and the third encapsulation layer 11.

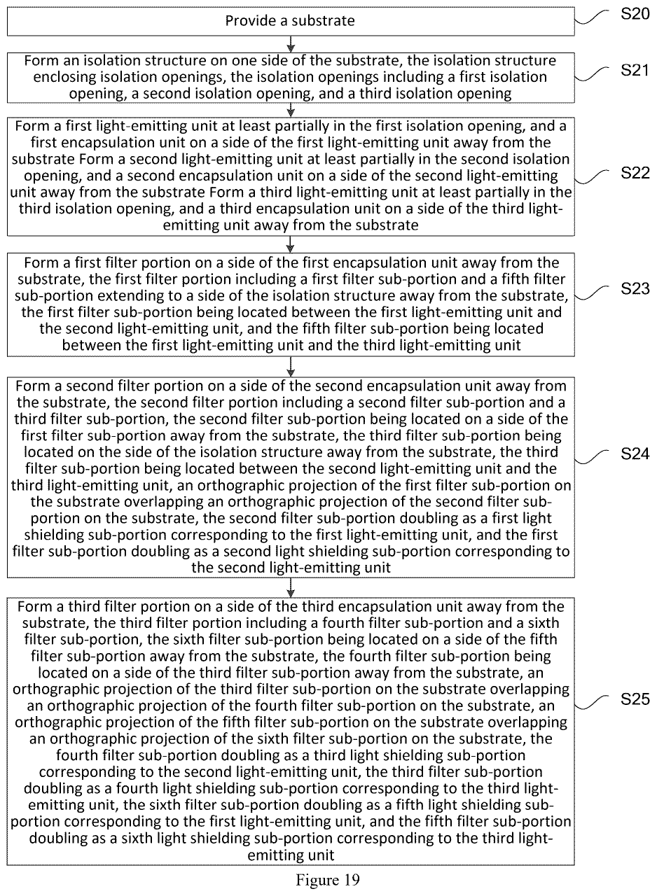

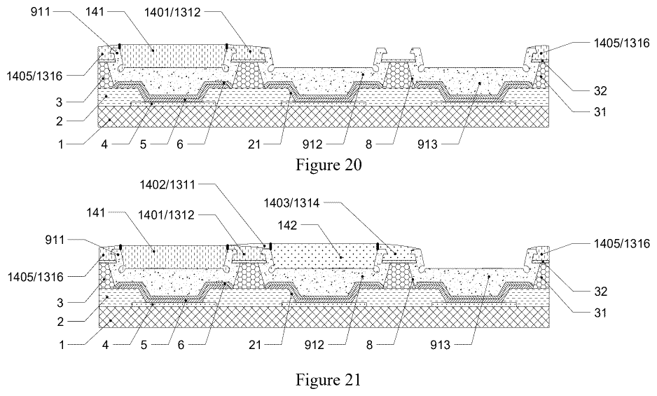

In some embodiments, referring to FIGS. 17 and 19, the present application further provides another method for preparing a display panel, the method including the following steps.
In step S20, a substrate 1 is provided.
In step S21, an isolation structure 3 is formed on one side of the substrate 1, the isolation structure 3 enclosing isolation openings 8, the isolation openings 8 including a first isolation opening 81, a second isolation opening 82, and a third isolation opening 83.
In step S22, a first light-emitting unit is at least partially formed in the first isolation opening 81, and a first encapsulation unit 911 is formed on a side of the first light-emitting unit away from the substrate 1; a second light-emitting unit is at least partially formed in the second isolation opening 82, and a second encapsulation unit 912 is formed on a side of the second light-emitting unit away from the substrate 1; and a third light-emitting unit is at least partially formed in the third isolation opening 83, and a third encapsulation unit 913 is formed on a side of the third light-emitting unit away from the substrate 1.
In step S23, referring to FIG. 20, a first filter portion 1411 is formed on a side of the first encapsulation unit 911 away from the substrate 1. The first filter portion 1411 includes a first filter sub-portion 1401 and a fifth filter sub-portion 1405 extending to a side of the isolation structure 3 away from the substrate 1. The first filter sub-portion 1401 is located between the first light-emitting unit and the second light-emitting unit, and the fifth filter sub-portion 1405 is located between the first light-emitting unit and the third light-emitting unit.
In step S24, referring to FIG. 21, a second filter portion 1412 is formed on a side of the second encapsulation unit 9112 away from the substrate 1. The second filter portion 1412 includes a second filter sub-portion 1402 and a third filter sub-portion 1403. The second filter sub-portion 1402 is located on a side of the first filter sub-portion 1401 away from the substrate 1, the third filter sub-portion 1403 is located on the side of the isolation structure 3 away from the substrate 1, and the third filter sub-portion 1403 is located between the second light-emitting unit and the third light-emitting unit. An orthographic projection of the first filter sub-portion 1401 on the substrate 1 overlaps an orthographic projection of the second filter sub-portion 1402 on the substrate 1. The second filter sub-portion 1402 doubles as a first light shielding sub-portion 1311 corresponding to the first light-emitting unit, and the first filter sub-portion 1401 doubles as a second light shielding sub-portion 1312 corresponding to the second light-emitting unit.

The light of the same color as that emitted by the first light-emitting unit may be transmitted through the first filter sub-portion 1401, but cannot be transmitted through the second filter sub-portion 1402, and the second filter sub-portion 1402 may be used as the first light shielding sub-portion 1311 for the first light-emitting unit. The first light shielding sub-portion 1311 can reduce the reflectivity of the ambient light of the same color as that emitted by the first light-emitting unit. In addition, the first light shielding sub-portion 1311 may be formed while forming the second filter portion 1412, without the need for a dedicated process for forming the first light shielding sub-portion 1311, and the cost of forming the first light shielding sub-portion 1311 can be reduced.

The light of the same color as that emitted by the second light-emitting unit may be transmitted through the second filter sub-portion 1402, but cannot be transmitted through the first filter sub-portion 1401, and the first filter sub-portion 1401 may be used as the second light shielding sub-portion 1312 for the second light-emitting unit. The second light shielding sub-portion 1312 can reduce the reflectivity of the ambient light of the same color as that emitted by the second light-emitting unit. In addition, the second light shielding sub-portion 1312 may be formed while forming the first filter portion 1411, without the need for a dedicated process for forming the second light shielding sub-portion 1312, and the cost of forming the second light shielding sub-portion 1312 can be reduced.
In step S25, referring again to FIG. 4c, a third filter portion 1413 is formed on a side of the third encapsulation unit 913 away from the substrate 1. The third filter portion 1413 includes a fourth filter sub-portion 1404 and a sixth filter sub-portion 1406. The sixth filter sub-portion 1406 is located on a side of the fifth filter sub-portion 1405 away from the substrate 1, and the fourth filter sub-portion 1404 is located on a side of the third filter sub-portion 1403 away from the substrate 1. An orthographic projection of the third filter sub-portion 1403 on the substrate 1 overlaps an orthographic projection of the fourth filter sub-portion 1404 on the substrate 1, and an orthographic projection of the fifth filter sub-portion 1405 on the substrate 1 overlaps an orthographic projection of the sixth filter sub-portion 1406 on the substrate 1. The fourth filter sub-portion 1404 doubles as a third light shielding sub-portion 1313 corresponding to the second light-emitting unit, the third filter sub-portion 1403 doubles as a fourth light shielding sub-portion 1314 corresponding to the third light-emitting unit, the sixth filter sub-portion 1406 doubles as a fifth light shielding sub-portion 1315 corresponding to the first light-emitting unit, and the fifth filter sub-portion 1405 doubles as a sixth light shielding sub-portion 1316 corresponding to the third light-emitting unit.

The light of the same color as that emitted by the second light-emitting unit may be transmitted through the third filter sub-portion 1403, but cannot be transmitted through the fourth filter sub-portion 1404, and the fourth filter sub-portion 1404 may be used as the third light shielding sub-portion 1313 for the second light-emitting unit. The third light shielding sub-portion 1313 can reduce the reflectivity of the ambient light of the same color as that emitted by the second light-emitting unit. In addition, the third light shielding sub-portion 1313 may be formed while forming the third filter portion 1413, without the need for a dedicated process for forming the third light shielding sub-portion 1313, and the cost of forming the third light shielding sub-portion 1313 can be reduced.

The light of the same color as that emitted by the third light-emitting unit may be transmitted through the fourth filter sub-portion 1404, but cannot be transmitted through the third filter sub-portion 1403, and the third filter sub-portion 1403 may be used as the fourth light shielding sub-portion 1314 for the third light-emitting unit. The fourth light shielding sub-portion 1314 can reduce the reflectivity of the ambient light of the same color as that emitted by the third light-emitting unit. In addition, the fourth light shielding sub-portion 1314 may be formed while forming the second filter portion 1412, without the need for a dedicated process for forming the fourth light shielding sub-portion 1314, and the cost of forming the fourth light shielding sub-portion 1314 can be reduced.

The light of the same color as that emitted by the first light-emitting unit may be transmitted through the fifth filter sub-portion 1405, but cannot be transmitted through the sixth filter sub-portion 1406, and the sixth filter sub-portion 1406 may be used as the fifth light shielding sub-portion 1315 for the first light-emitting unit. The fifth light shielding sub-portion 1315 can reduce the reflectivity of the ambient light of the same color as that emitted by the first light-emitting unit. In addition, the fifth light shielding sub-portion 1315 may be formed while forming the third filter portion 1413, without the need for a dedicated process for forming the fifth light shielding sub-portion 1315, and the cost of forming the fifth light shielding sub-portion 1315 can be reduced.

The light of the same color as that emitted by the third light-emitting unit may be transmitted through the sixth filter sub-portion 1406, but cannot be transmitted through the fifth filter sub-portion 1405, and the fifth filter sub-portion 1405 may be used as the sixth light shielding sub-portion 1316 for the third light-emitting unit. The sixth light shielding sub-portion 1316 can reduce the reflectivity of the ambient light of the same color as that emitted by the third light-emitting unit. In addition, the sixth light shielding sub-portion 1316 may be formed while forming the first filter portion 1411, without the need for a dedicated process for forming the sixth light shielding sub-portion 1316, and the cost of forming the sixth light shielding sub-portion 1316 can be reduced.

During the process of forming the first filter portion 1411, the second filter portion 1412, and the third filter portion 1413 by the above method, the first filter portion 1411 and the second filter portion 1412, the second filter portion 1412 and the third filter portion 1413, and the first filter portion 1411 and the third filter portion 1413 overlap on the side of the isolation structure 3 away from the substrate 1, respectively, and the overlapped portions of the filter portions may form the light shielding portions corresponding to the first light-emitting unit, the second light-emitting unit, and the third light-emitting unit. In this way, the light shielding portions corresponding to the first light-emitting unit, the second light-emitting unit, and the third light-emitting unit can be formed while forming the first filter portion 1411, the second filter portion 1412, and the third filter portion 1413, without the need for a dedicated process for forming the corresponding light shielding portions, and the process cost of forming the light shielding portions can be reduced.

In some embodiments, the present application further provides an electronic device, including a display panel in the present application, or including a display panel prepared by means of a method for preparing a display panel in the present application. The electronic device may include a device having image processing capability, for example, a server, a personal computer, a notebook computer, etc. Since the electronic device includes the display panel in the present application, the electronic device has a better display quality.

The features in the above embodiments may be combined in any manner. For the purpose of simplicity in description, not all possible combinations of the features in the above-described embodiments are described. However, as long as the combinations of these features do not conflict with each other, the combinations shall all fall within the scope of the description.

The above embodiments merely represent several implementations of the present application, giving specifics and details thereof, but should not be understood as limiting the scope of the present application thereby. It should be noted that various variations and improvements may also be made without departing from the spirit of the present application and shall fall within the scope of protection of the present application. Therefore, the scope of protection of the present application shall be in accordance with the appended claims.

1. A display panel, comprising:
a substrate;
an isolation structure located on one side of the substrate, the isolation structure enclosing isolation openings;
light-emitting units at least partially located in the isolation openings; encapsulation units located on a side of the light-emitting units away from the substrate, at least part of the encapsulation unit extending from a side surface of the isolation structure facing the isolation opening to a side of the isolation structure away from the substrate;
a filter layer located on the side of the light-emitting unit away from the substrate and comprising a plurality of filter portions disposed at intervals, an orthographic projection of the filter portion on the substrate at least partially overlapping an orthographic projection of the light-emitting unit on the substrate; and
a light shielding layer located on the side of the isolation structure away from the substrate, the light shielding layer comprising a plurality of light shielding portions disposed at intervals, wherein an orthographic projection of the light shielding portion on the substrate at least partially overlaps an orthographic projection of the isolation structure on the substrate; and the orthographic projection of the light shielding portion on the substrate at least partially overlaps the orthographic projection of the filter portion on the substrate.

2. The display panel according to claim 1, wherein part of the light shielding portion extends to a side of the filter portion away from the substrate;
the display panel further comprises a pixel defining layer located on one side of the substrate, the isolation structure being located on a side of the pixel defining layer away from the substrate; the pixel defining layer comprises a plurality of pixel openings disposed at intervals, an orthographic projection of the pixel opening on the substrate being located within a range of an orthographic projection of the isolation opening on the substrate, and part of the light-emitting unit being located in the pixel opening; and
the orthographic projection of the filter portion on the substrate at least partially overlaps the orthographic projection of the isolation structure on the substrate, wherein the light shielding portion is located on a side, close to the isolation structure, of a line connecting an edge of the pixel opening and an edge of the isolation opening;
the isolation structure and the pixel defining layer have a pixel isolation cross-section in any direction extending along a centerline of the light-emitting unit, the pixel defining layer has a first edge point on either side of the pixel isolation cross-section close to the isolation opening, the isolation structure has a second edge point on either side of the pixel isolation cross-section close to the isolation opening, an edge line is formed between the first edge point and the second edge point on the same side of the pixel isolation cross-section, and an edge of the light shielding portion is located on a side of the edge line away from the isolation opening; and
the edge lines of the pixel isolation cross-section comprise a first sub-edge line and a second sub-edge line disposed on different sides of the pixel isolation cross-section, and the light shielding portion located on a side of the pixel isolation cross-section facing away from the substrate is located within a range formed by the first sub-edge line, the second sub-edge line and the pixel isolation cross-section.

3. The display panel according to claim 2, wherein an orthographic projection on the substrate of a side of the light shielding portion close to the isolation opening is located between an edge of the orthographic projection of the pixel opening on the substrate and an edge of the orthographic projection of the isolation opening on the substrate
wherein the light-emitting units comprise a first light-emitting unit, a second light-emitting unit and a third light-emitting unit of different light-emitting colors, wherein a minimum distance between an orthographic projection on the substrate of a side facing the isolation opening of the light shielding portion corresponding to the second light-emitting unit and the edge of the orthographic projection of the pixel opening on the substrate is greater than a minimum distance between an orthographic projection on the substrate of a side facing the isolation opening of the light shielding portion corresponding to each of the first light-emitting unit and the third light-emitting unit and the edge of the orthographic projection of the pixel opening on the substrate.

4. The display panel according to claim 1, wherein the light-emitting units comprise a first light-emitting unit, a second light-emitting unit, and a third light-emitting unit of different light-emitting colors, wherein in a thickness direction of the substrate, a thickness of the filter portion of the second light-emitting unit is greater than a thickness of the filter portion of each of the first light-emitting unit and the third light-emitting unit;
the thickness of the filter portion located on a side of the first light-emitting unit facing away from the substrate is greater than the thickness of the filter portion located on a side of the third light-emitting unit facing away from the substrate; and
the first light-emitting unit has a greater light-emitting wavelength than the second light-emitting unit, or the second light-emitting unit has a greater light-emitting wavelength than the third light-emitting unit.

5. The display panel according to claim 1, wherein a thickness of the light shielding portion is greater than or equal to 1 μm and less than or equal to 3 μm in a thickness direction of the substrate; and
a color of the filter portion is the same as a light-emitting color of the light-emitting unit located on a side of the filter portion close to the substrate.

6. The display panel according to claim 1, wherein the light-emitting units comprise a first light-emitting unit, a second light-emitting unit, and a third light-emitting unit of different light-emitting colors, and the filter portions comprise a first filter portion, a second filter portion, and a third filter portion, the first filter portion being located on a side of the first light-emitting unit away from the substrate, the second filter portion being located on a side of the second light-emitting unit away from the substrate, and the third filter portion being located on a side of the third light-emitting unit away from the substrate; and
the display panel further comprises a pixel defining layer on one side of the substrate, the pixel defining layer comprising a plurality of pixel openings disposed at intervals,
wherein a minimum distance between an orthographic projection on the substrate of a side facing the isolation opening of the light shielding portion corresponding to the second light-emitting unit and an edge of the orthographic projection of the pixel opening on the substrate is greater than a minimum distance between an orthographic projection on the substrate of a side facing the isolation opening of the light shielding portion corresponding to each of the first light-emitting unit and the third light-emitting unit and the edge of the orthographic projection of the pixel opening on the substrate.

7. The display panel according to claim 6, wherein the first filter portion comprises a first filter sub-portion extending to the side of the isolation structure away from the substrate, the first filter sub-portion being located between the first light-emitting unit and the second light-emitting unit, and the second filter portion comprises a second filter sub-portion extending to a side of the first filter sub-portion away from the substrate, an orthographic projection of the first filter sub-portion on the substrate overlapping an orthographic projection of the second filter sub-portion on the substrate;
the light shielding portion comprises a first light shielding sub-portion located on the side of the first filter sub-portion away from the substrate, the first light shielding sub-portion being located between the first light-emitting unit and the second light-emitting unit, and an orthographic projection of the first light shielding sub-portion on the substrate overlapping the orthographic projection of the first filter sub-portion on the substrate;
the first light shielding sub-portion corresponding to the first light-emitting unit comprises the second filter sub-portion;
the light shielding portion comprises a second light shielding sub-portion located on a side of the second filter sub-portion close to the substrate, the second light shielding sub-portion being located between the first light-emitting unit and the second light-emitting unit, and an orthographic projection of the second light shielding sub-portion on the substrate overlapping the orthographic projection of the second filter sub-portion on the substrate; and
the second light shielding sub-portion corresponding to the second light-emitting unit comprises the first filter sub-portion.

8. The display panel according to claim 7, wherein the second filter portion comprises a third filter sub-portion extending to the side of the isolation structure away from the substrate, the third filter sub-portion being located between the second light-emitting unit and the third light-emitting unit, and the third filter portion comprises a fourth filter sub-portion extending to a side of the third filter sub-portion away from the substrate, an orthographic projection of the third filter sub-portion on the substrate overlapping an orthographic projection of the fourth filter sub-portion on the substrate;
the light shielding portion comprises a third light shielding sub-portion located on the side of the third filter sub-portion away from the substrate, the third light shielding sub-portion being located between the second light-emitting unit and the third light-emitting unit, and an orthographic projection of the third light shielding sub-portion on the substrate overlapping the orthographic projection of the third filter sub-portion on the substrate;
the third light shielding sub-portion corresponding to the second light-emitting unit comprises the fourth filter sub-portion;
the light shielding portion comprises a fourth light shielding sub-portion located on a side of the fourth filter sub-portion close to the substrate, the fourth light shielding sub-portion being located between the second light-emitting unit and the third light-emitting unit, and an orthographic projection of the fourth light shielding sub-portion on the substrate overlapping the orthographic projection of the fourth filter sub-portion on the substrate; and
the fourth light shielding sub-portion corresponding to the third light-emitting unit comprises the third filter sub-portion.

9. The display panel according to claim 8, wherein the first filter portion further comprises a fifth filter sub-portion extending to the side of the isolation structure away from the substrate, the fifth filter sub-portion being located between the first light-emitting unit and the third light-emitting unit, and the third filter portion comprises a sixth filter sub-portion extending to a side of the fifth filter sub-portion away from the substrate, an orthographic projection of the fifth filter sub-portion on the substrate overlapping an orthographic projection of the sixth filter sub-portion on the substrate;
the light shielding portion comprises a fifth light shielding sub-portion located on the side of the fifth filter sub-portion away from the substrate, the fifth light shielding sub-portion being located between the first light-emitting unit and the third light-emitting unit, and an orthographic projection of the fifth light shielding sub-portion on the substrate overlapping the orthographic projection of the fifth filter sub-portion on the substrate;
the fifth light shielding sub-portion corresponding to the first light-emitting unit comprises the sixth filter sub-portion;
the light shielding portion comprises a sixth light shielding sub-portion located on a side of the sixth filter sub-portion close to the substrate, the sixth light shielding sub-portion being located between the first light-emitting unit and the third light-emitting unit, and an orthographic projection of the sixth light shielding sub-portion on the substrate overlapping the orthographic projection of the sixth filter sub-portion on the substrate; and
the sixth light shielding sub-portion corresponding to the third light-emitting unit comprises the fifth filter sub-portion.

10. The display panel according to claim 9, wherein a minimum distance between an orthographic projection on the substrate of a side of the first light shielding sub-portion facing the first light-emitting unit and an edge of the orthographic projection on the substrate of the pixel opening for the first light-emitting unit is greater than or equal to 0 and less than or equal to 5 μm.

11. The display panel according to claim 1, further comprising a pixel defining layer located on one side of the substrate, wherein the isolation structure is located on a side of the pixel defining layer away from the substrate; the pixel defining layer comprises a plurality of pixel openings disposed at intervals, an orthographic projection of the pixel opening on the substrate comprising a first edge and a second edge connected to each other, wherein an extension length of the first edge is greater than an extension length of the second edge; and
a minimum distance between an orthographic projection on the substrate of a side of the light shielding portion close to the isolation opening and the first edge is greater than a minimum distance between the orthographic projection on the substrate of the side of the light shielding portion close to the isolation opening and the second edge.

12. The display panel according to claim 1, wherein a side of the encapsulation unit away from the substrate is in contact with a side of the filter portion close to the substrate;
the encapsulation units are spaced apart on the side of the isolation structure away from the substrate;
at least part of the light shielding portion is located between adjacent two of the encapsulation units;
a gap is provided between the encapsulation unit located on the side of the isolation structure away from the substrate and the side of the isolation structure away from the substrate;
the filter portion or the light shielding portion fills at least part of the gap; and
an orthographic projection of the encapsulation unit on the substrate covers an orthographic projection of the isolation opening on the substrate, and covers part of the orthographic projection of the isolation structure on the substrate.

13. The display panel according to claim 1, further comprising a second encapsulation layer located on a side of the encapsulation units away from the substrate, and a third encapsulation layer located on a side of the second encapsulation layer away from the substrate, wherein
the isolation structure comprises a first isolation portion and a second isolation portion sequentially stacked in a direction away from the substrate, an orthographic projection on the substrate of a side of the first isolation portion away from the substrate being located within an orthographic projection of the second isolation portion on the substrate; and
the light-emitting unit comprises a first electrode, a light-emitting portion and a second electrode sequentially stacked in the direction away from the substrate.

14. A display panel, comprising:
a substrate;
a pixel defining layer comprising a plurality of pixel openings disposed at intervals;
an isolation structure located on a side of the pixel defining layer away from the substrate, the isolation structure enclosing isolation openings, and the pixel openings being in communication with the isolation openings;
light-emitting units at least partially located in the isolation openings; encapsulation units located on a side of the light-emitting units away from the substrate, at least part of the encapsulation unit extending from a side surface of the isolation structure facing the isolation opening to a side of the isolation structure away from the substrate;
a filter layer located on the side of the light-emitting unit away from the substrate and comprising a plurality of filter portions disposed at intervals, an orthographic projection of the filter portion on the substrate at least partially overlapping an orthographic projection of the light-emitting unit on the substrate; and
a light shielding layer located on the side of the isolation structure away from the substrate, the light shielding layer comprising a plurality of light shielding portions disposed at intervals, wherein an orthographic projection of the light shielding portion on the substrate at least partially overlaps an orthographic projection of the isolation structure on the substrate, part of the light shielding portion extends to a side of the filter portion away from the substrate, and the light shielding portion is located on a side, close to the isolation structure, of a line connecting an edge of the pixel opening and an edge of the isolation opening.

15. The display panel according to claim 14, wherein the isolation structure and the pixel defining layer have a pixel isolation cross-section in any direction extending along a centerline of the light-emitting unit, the pixel defining layer has a first edge point on either side of the pixel isolation cross-section close to the isolation opening, the isolation structure has a second edge point on either side of the pixel isolation cross-section close to the isolation opening, an edge line is formed between the first edge point and the second edge point on the same side of the pixel isolation cross-section, and an edge of the light shielding portion is located on a side of the edge line away from the isolation opening; and
the edge lines of the pixel isolation cross-section comprise a first sub-edge line and a second sub-edge line disposed on different sides of the isolation cross-section, and the light shielding portion located on a side of the isolation cross-section facing away from the substrate is located within a range of a pattern formed by the first sub-edge line, the second sub-edge line and the isolation cross-section.

16. A method for preparing a display panel, the method comprising:
forming an isolation structure on one side of a substrate, the isolation structure enclosing isolation openings;
forming light-emitting units at least partially in the isolation openings, encapsulation units on a side of the light-emitting units away from the substrate, and a filter layer on a side of the encapsulation units away from the substrate, the filter layer comprising a plurality of filter portions disposed at intervals, an orthographic projection of the filter portion on the substrate at least partially overlapping an orthographic projection of the light-emitting unit on the substrate; and
forming a light shielding layer on a side of the isolation structure away from the substrate, the light shielding layer comprising a plurality of light shielding portions disposed at intervals, an orthographic projection of the light shielding portion on the substrate at least partially overlapping an orthographic projection of the isolation structure on the substrate, and the orthographic projection of the light shielding portion on the substrate at least partially overlapping the orthographic projection of the filter portion on the substrate.

17. The method for preparing a display panel according to claim 16, wherein the light-emitting units comprise a first light-emitting unit, a second light-emitting unit, and a third light-emitting unit, the isolation openings comprise a first isolation opening, a second isolation opening, and a third isolation opening, and the filter layer comprises a first filter portion, a second filter portion, and a third filter portion; and
the step of forming light-emitting units at least partially in the isolation openings, encapsulation units on a side of the light-emitting units away from the substrate, and a filter layer on a side of the encapsulation units away from the substrate comprises:
forming the first light-emitting unit in the first isolation opening and an encapsulation unit on a side of the first light-emitting unit away from the substrate, and forming the first filter portion on a side, away from the substrate, of the encapsulation unit for the first light-emitting unit, an orthographic projection of the first filter portion on the substrate covering an orthographic projection of the first light-emitting unit on the substrate;
forming the second light-emitting unit in the second isolation opening and an encapsulation unit on a side of the second light-emitting unit away from the substrate, and forming the second filter portion on a side, away from the substrate, of the encapsulation unit for the second light-emitting unit, an orthographic projection of the second filter portion on the substrate covering an orthographic projection of the second light-emitting unit on the substrate; and
forming the third light-emitting unit in the third isolation opening and an encapsulation unit on a side of the third light-emitting unit away from the substrate, and forming the third filter portion on a side, away from the substrate, of the encapsulation unit for the third light-emitting unit, an orthographic projection of the third filter portion on the substrate covering an orthographic projection of the third light-emitting unit on the substrate,
wherein a filter color of the first filter portion is the same as a light-emitting color of the first light-emitting unit, a filter color of the second filter portion is the same as a light-emitting color of the second light-emitting unit, and a filter color of the third filter portion is the same as a light-emitting color of the third light-emitting unit.

18. The method for preparing a display panel according to claim 17, wherein the light-emitting units comprise a first light-emitting unit, a second light-emitting unit, and a third light-emitting unit, and the isolation openings comprise a first isolation opening, a second isolation opening, and a third isolation opening; and
the step of forming light-emitting units at least partially in the isolation openings, encapsulation units on a side of the light-emitting units away from the substrate, and a filter layer on a side of the encapsulation units away from the substrate comprises:
forming the first light-emitting unit in the first isolation opening and an encapsulation unit on a side of the first light-emitting unit away from the substrate; forming the second light-emitting unit in the second isolation opening and an encapsulation unit on a side of the second light-emitting unit away from the substrate;
forming the third light-emitting unit in the third isolation opening and an encapsulation unit on a side of the third light-emitting unit away from the substrate; and
forming a filter layer on a side of the encapsulation units away from the substrate, the filter layer comprising a first filter portion, a second filter portion, and a third filter portion, wherein an orthographic projection of the first filter portion on the substrate covering an orthographic projection of the first light-emitting unit on the substrate, an orthographic projection of the second filter portion on the substrate covers an orthographic projection of the second light-emitting unit on the substrate, and an orthographic projection of the third filter portion on the substrate covers an orthographic projection of the third light-emitting unit on the substrate; and
a filter color of the first filter portion is the same as a light-emitting color of the first light-emitting unit, a filter color of the second filter portion is the same as a light-emitting color of the second light-emitting unit, and a filter color of the third filter portion is the same as a light-emitting color of the third light-emitting unit.

19. The method for preparing a display panel according to claim 18, further comprising, after the step of forming a light shielding layer on a side of the isolation structure away from the substrate:
forming a second encapsulation layer on a side of the filter layer and the light shielding layer away from the substrate; and
forming a third encapsulation layer on a side of the second encapsulation layer away from the substrate.

20. An electronic device, comprising a display panel according to claim 1.
